(19) United States
(12) Patent Application Publication
(10) Pub. No.: US 2024/0431105 A1
(43) Pub. Date: Dec. 26, 2024

(54) SEMICONDUCTOR MEMORY DEVICE AND ELECTRONIC SYSTEM INCLUDING THE SAME

(71) Applicant: Samsung Electronics Co., Ltd., Suwon-si (KR)

(72) Inventors: Young Sik Lee, Suwon-si (KR); Yeon Su Kim, Suwon-si (KR); Hwan Chul Jeon, Suwon-si (KR)

(21) Appl. No.: 18/748,242

(22) Filed: Jun. 20, 2024

(30) Foreign Application Priority Data
Jun. 26, 2023 (KR) 10-2023-0081876

(51) Int. Cl. H10B 43/27

(52) U.S. Cl. CPC H10B 43/27

(57) ABSTRACT

A semiconductor memory device and electronic system including the same are provided. The semiconductor memory device may include a first stacked structure including a plurality of first interlayer insulating films, a second stacked structure including a plurality of second interlayer insulating films on the first stacked structure, and a hole that extends into the first stacked structure and the second stacked structure. The plurality of second interlayer insulating films may include a plurality of first films that include first impurities, and a plurality of second films that are free of the first impurities.

### CROSS-REFERENCE TO RELATED APPLICATION

This application claims priority under 35 U.S.C. 119 from Korean Patent Application No. 10-2023-0081876, filed on Jun. 26, 2023 in the Korean Intellectual Property Office, the contents of which in its entirety are herein incorporated by reference.

### BACKGROUND

The present disclosure relates to a semiconductor memory device and an electronic system including the same.

There is a need for a semiconductor memory device that can store a large capacity of data in an electronic system that requires data storage. Therefore, research into ways capable of increasing the data storage capacity of the semiconductor memory device is being conducted. For example, as one method for increasing the data storage capacity of the semiconductor memory device, a semiconductor memory device including memory cells arranged three-dimensionally instead of memory cells arranged two-dimensionally has been proposed.

### SUMMARY

Aspects of the present disclosure provide a semiconductor memory device that includes a hole that penetrates (i.e., extends into) a plurality of stacks and has side walls including no step.

Aspects of the present disclosure also provide an electronic system including the semiconductor memory device that includes a hole that penetrates (i.e., extends into) a plurality of stacks and has side walls including no step.

However, aspects of the present disclosure are not restricted to the ones set forth herein. The above and other aspects of the present disclosure will become more apparent to one of ordinary skill in the art to which the present disclosure pertains by referencing the detailed description of the present disclosure given below.

According to some aspects of the present disclosure, there is provided a semiconductor memory device including a first stacked structure including a plurality of first interlayer insulating films, a second stacked structure including a plurality of second interlayer insulating films on the first stacked structure, and a hole that extends into the first stacked structure and the second stacked structure. The plurality of second interlayer insulating films may include a plurality of first films that include first impurities, and a plurality of second films that are free of the first impurities.

According to some aspects of the present disclosure, there is provided a semiconductor memory device including a first stacked structure including a plurality of first interlayer insulating films, a second stacked structure including a plurality of second interlayer insulating films on the first stacked structure, and a hole that extends into the first stacked structure and the second stacked structure. The plurality of second interlayer insulating films may include a plurality of first films on the first stacked structure, and a plurality of second films on the plurality of first films. One of the plurality of first interlayer insulating films that is closest to the second stacked structure may be free of impurities. One of the plurality of first films that is closest to the first stacked structure may include the impurities.

According to some aspects of the present disclosure, there is provided an electronic system including a main board, a semiconductor memory device on the main board, and a controller electrically connected to the semiconductor memory device on the main board. The semiconductor memory device includes a cell substrate, a first mold stack including a plurality of first gate electrodes and a plurality of first mold insulating films alternately stacked on the cell substrate, a second mold stack including a plurality of second gate electrodes and a plurality of second mold insulating films alternately stacked on the first mold stack, and a channel structure that extends into the first mold stack and the second mold stack. The plurality of second mold insulating films may include a plurality of first insulating films that include impurities, and a plurality of second insulating films that are free of the impurities. The channel structure may be free of a stepped portion.

### BRIEF DESCRIPTION OF THE DRAWINGS

The above and other aspects and features of the present disclosure will become more apparent by describing in detail example embodiments thereof with reference to the attached drawings, in which:

FIG. 1 is a diagram for explaining a semiconductor memory device according to some embodiments;

FIGS. 2 and 3 are enlarged views of a region R of FIG. 1;

FIG. 4 is a diagram for explaining the semiconductor memory device according to some embodiments;

FIGS. 5 and 6 are enlarged views of a region R of FIG. 4;

FIGS. 7 and 8 are diagrams for explaining a method for fabricating a semiconductor memory device according to some embodiments.

FIGS. 9 and 10 are diagrams for explaining the method for fabricating the semiconductor memory device according to some embodiments.

FIG. 11 is an example block diagram for explaining a semiconductor memory device according to some embodiments;

FIG. 12 is an example circuit diagram for explaining the semiconductor memory device according to some embodiments;

FIG. 13 is a schematic layout diagram for explaining the semiconductor memory device according to some embodiments;

FIG. 14 is a cross-sectional view taken along line A-A′ of FIG. 13;

FIG. 15 is an enlarged view of a region S1 of FIG. 14;

FIG. 16 is a cross-sectional view taken along line B-B′ of FIG. 13;

FIG. 17 is a diagram for explaining a semiconductor memory device according to some embodiments;

FIG. 18 is an enlarged view of a region S2 of FIG. 17;

FIGS. 19 and 20 are diagrams for explaining a semiconductor memory device according to some embodiments;

FIG. 21 is a diagram for explaining a semiconductor memory device according to some embodiments;

FIGS. 22 to 24 are intermediate step diagrams for explaining the method for fabricating the semiconductor memory device according to some embodiments;

FIG. 25 is an example block diagram for explaining an electronic system according to some embodiments;

FIG. 26 is an example perspective view for explaining the electronic system according to some embodiments; and

FIG. 27 is a schematic cross-sectional view taken along line I-I of FIG. 26.

### DETAILED DESCRIPTION

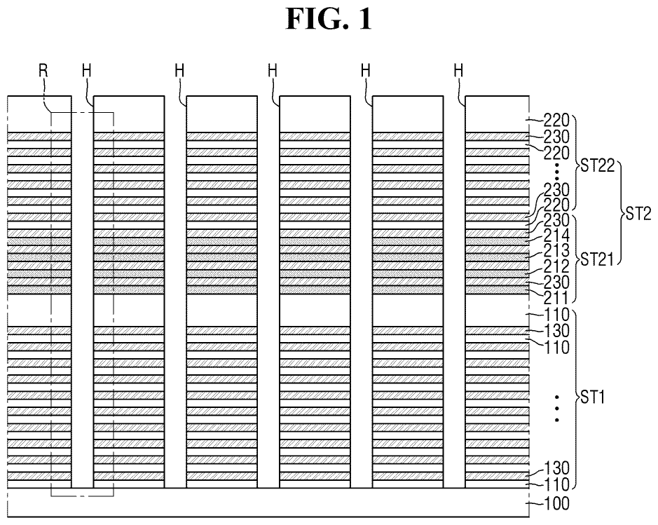

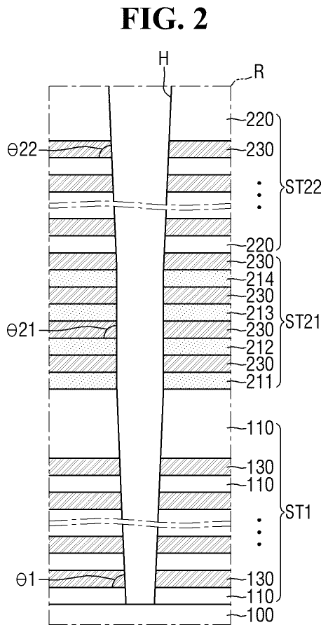

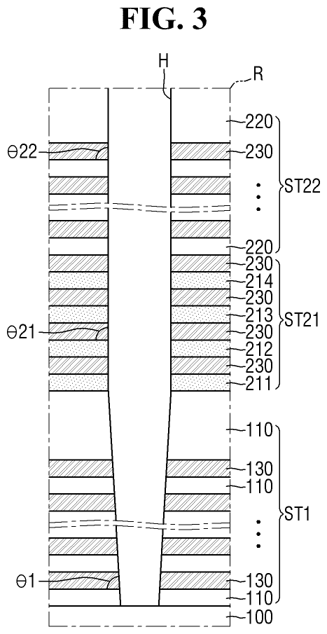

FIG. 1 is a diagram for explaining a semiconductor memory device according to some embodiments. FIGS. 2 and 3 are enlarged views of a region R of FIG. 1.

Referring to FIG. 1, the semiconductor memory device according to some embodiments includes a cell substrate 100, a first stacked structure ST1, a second stacked structure ST2, and a hole H.

The cell substrate 100 may include a semiconductor substrate such as, for example, a silicon substrate, a germanium substrate or a silicon-germanium substrate. As another example, the cell substrate 100 may include a silicon-on-insulator (SOI) substrate, a germanium-on-insulator (GOI) substrate, or the like. In some embodiments, the cell substrate 100 may include impurities. For example, the cell substrate 100 may include n-type impurities (e.g., phosphorus (P), arsenic (As), etc.).

The first stacked structure ST1 is placed on the cell substrate 100. The first stacked structure ST1 includes a plurality of first interlayer insulating films 110 and a plurality of first sacrificial films 130 that are alternately stacked. The first interlayer insulating film 110 and the first sacrificial film 130 may include different materials from each other. For example, the first interlayer insulating film 110 may include silicon oxide, and the first sacrificial film 130 may include, for example, silicon nitride.

The second stacked structure ST2 is placed on the first stacked structure ST1. The second stacked structure ST2 includes a plurality of second interlayer insulating films 211, 212, 213, 214, and 220 and a plurality of second sacrificial films 230 that are alternately stacked. The second interlayer insulating films 211, 212, 213, 214, and 220 and the second sacrificial films 230 may include different materials from each other. For example, the second interlayer insulating films 211, 212, 213, 214, and 220 may include silicon oxide, and the second sacrificial films 230 may include, for example, silicon nitride.

The plurality of second interlayer insulating films 211, 212, 213, 214, and 220 include a plurality of first films 211, 212, 213, and 214 including impurities, and a plurality of second films 220 not including impurities. In other words, the plurality of first films 211, 212, 213, and 214 may include impurities, and the plurality of second films 220 may be free of impurities. The plurality of first films 211, 212, 213, and 214 are placed between the first stacked structure ST1 and the plurality of second films 220. The plurality of first films 211, 212, 213, and 214 may be doped with impurities. In other words, the second stacked structure ST2 includes a second-1 stacked structure ST21 including a plurality of first films 211, 212, 213, and 214 and second sacrificial films 230 that are alternately stacked, and a second-2 stacked structure ST22 including a plurality of second films 220 and second sacrificial films 230 that are alternately stacked. The second-1 stacked structure ST21 is placed between the first stacked structure ST1 and the second-2 stacked structure ST22. The number of first films 211, 212, 213, and 214 and the number of second films 220 are exemplary only and are not limited to those shown.

The impurities may be, for example, any one of fluorine (F) and phosphorus (P). For example, the impurities may include at least one of fluorine (F) or phosphorus (P). The concentration of impurities in each of the first films 211, 212, 213, and 214 may be different. The concentration of impurities in each of the first films 211, 212, 213, and 214 may increase (for example, gradually) toward the first stacked structure ST1. For example, the concentration of impurities in the first-1 film 211 may be higher than the concentration of impurities in the first-2 film 212, and the concentration of impurities in the first-2 film 212 may be higher than that in the first-3 insulating film 213, and the concentration of impurities in the first-3 insulating film 213 may be higher than the concentration of impurities in the first-4 insulating film 214. The plurality of first interlayer insulating films 110 may not include impurities.

The hole H may extend in a direction perpendicular to an upper face of the cell substrate 100 inside the stacked structures ST1 and ST2. The hole H may penetrate (i.e., extend) through the stacked structures ST1 and ST2. Hereinafter, the surface of the cell substrate 100 on which the stacked structures ST1 and ST2 are placed may be referred to as an upper face of the cell substrate 100. Hereinafter, an uppermost part and a lowermost part (also referred to as an uppermost portion and a lowermost portion, respectively) are defined on the basis of a direction perpendicular to the upper face of the cell substrate 100. Hereinafter, a slope is defined on the basis of the direction parallel to the upper face of the cell substrate 100. For example, the slope may be an angle of inclination with respect to a plane that is parallel to the upper face of the cell substrate 100. Hereinafter, a width is defined on the basis of the direction parallel to the upper face of the cell substrate 100.

A side wall of the hole H may not include a step. That is, a side wall of the hole H may be free of a step or, said another way, may be free of a stepped portion. For example, a side wall of the hole H may not have a stepped profile. The width of the hole H at the uppermost part of the first stacked structure ST1 may be substantially the same as the width of the hole H at the lowermost part of the second stacked structure ST2 (e.g., the lowermost part of the second-1 stacked structure ST21).

In the semiconductor memory device according to some embodiments, the hole H may include portions in which slopes of the side walls are different from each other.

Referring to FIGS. 2 and 3, a slope θ21 of the side wall of the hole H in the second-1 stacked structure ST21 may be greater than a slope 01 of the side wall of the hole H in the first stacked structure ST1. The slope θ21 of the side wall of the hole H in the second-1 stacked structure ST21 may be 90 degrees, for example. The width of the hole H in the second-1 stacked structure ST21 may be constant. For example, a first portion of the hole H may be in the first stacked structure ST1 and may have side walls with the slope θ1, a second portion of the hole H may be in the second-1 stacked structure ST21 and may have side walls with the slope θ21, and a third portion of the hole H may be in the second-2 stacked structure ST22 and may have side walls with the slope θ22.

Referring to FIG. 2, in some embodiments, the slope θ21 of the side wall of the hole H in the second-1 stacked structure ST21 may be different from a slope θ22 of the side wall of the hole H in the second-2 stacked structure ST22. The slope θ21 of the side wall of the hole H in the second-1 stacked structure ST21 may be greater than the slope θ22 of side wall of the hole H in the second-2 stacked structure ST22.

Referring to FIG. 3, in some embodiments, the slope θ21 of the side wall of the hole H in the second-1 stacked structure ST21 may be the same as the slope θ22 of the side wall of the hole H in the second-2 stacked structure ST22. A width of the hole H in the second stacked structure ST2 may be constant. The slope of the side walls θ22 of the hole H in the second-second stacked structure ST22 may be greater than the slope θ1 of the side wall of the hole H in the first stacked structure ST1.

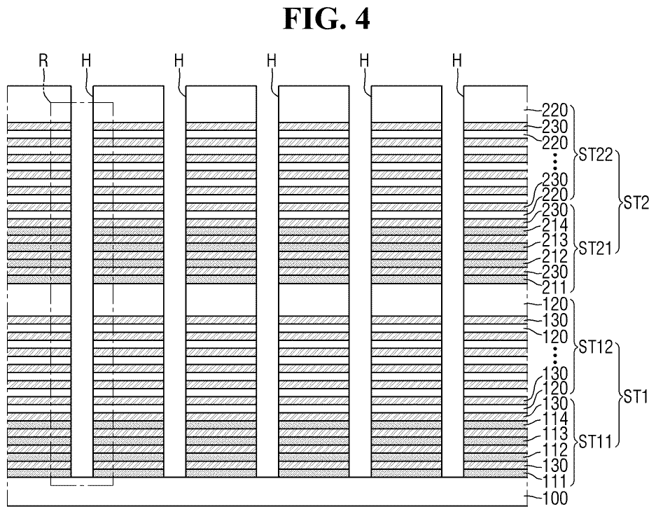

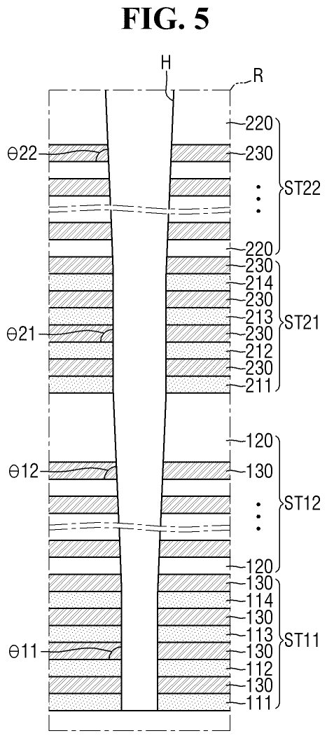

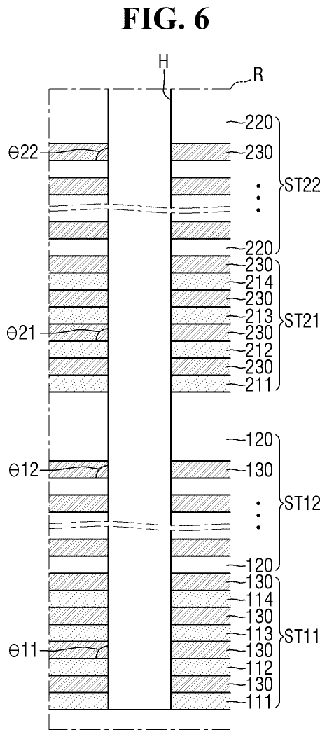

FIG. 4 is a diagram for explaining a semiconductor memory device according to some embodiments. FIGS. 5 and 6 are enlarged views of the region R of FIG. 4. For convenience of explanation, repeated parts of contents explained above with reference to FIGS. 1 to 3 will be briefly explained or omitted.

Referring to FIG. 4, in the semiconductor memory device according to some embodiments, a first stacked structure ST1 includes a plurality of first interlayer insulating films 111, 112, 113, 114, and 120 and a plurality of first sacrificial films 130 that are alternately stacked. The plurality of first interlayer insulating films 111, 112, 113, 114 and 120 include a plurality of third films 111, 112, 113 and 114 including impurities, and a plurality of fourth films 120 not including impurities. In other words, the plurality of third films 111, 112, 113, and 114 may include impurities, and the plurality of fourth films 120 may be free of impurities. The plurality of fourth films 120 are placed between the plurality of third films 111, 112, 113, and 114 and the second stacked structure ST2. In other words, the first stacked structure ST1 includes the first-1 stacked structure ST11 including the plurality of third films 111, 112, 113, and 114 and the first sacrificial films 130 that are alternately stacked, and the first-2 stacked structure ST12 including the plurality of fourth films 120 and the first sacrificial films 130 that are alternately stacked. The first-2 stacked structure ST12 is placed between the first-1 stacked structure ST11 and the second-1 stacked structure ST21. The number of third films 111, 112, 113, and 114 and the number of fourth films 120 are merely exemplary and are not limited to those shown.

The third films 111, 112, 113, 114, the fourth films 120, and the first sacrificial films 130 may include different materials. For example, the third films 111, 112, 113, 114 and the fourth films 120 may include silicon oxide, and the first sacrificial films 130 may include silicon nitride.

The impurities may be, for example, any one of fluorine (F) and phosphorus (P). For example, the impurities may include at least one of fluorine (F) or phosphorus (P). The impurities doped in the third films 111, 112, 113, and 114 may be the same as or different from the impurities doped in the first films 211, 212, 213, and 214. The concentration of impurities in each of the third films 111, 112, 113, and 114 may be different. The concentration of impurities in each of the third films 111, 112, 113, and 114 may increase as it goes away from the second stacked structure ST2 (e.g., may decrease toward the second stacked structure ST2). The concentration of impurities in the third films 111, 112, 113, and 114 may gradually increase, as it goes away from the second stacked structure ST2. For example, the concentration of impurities in the third-1 film 111 may be higher than the concentration of impurities in the third-2 film 112, the concentration of impurities in the third-2 film 112 may be higher than the concentration of impurities in the third-3 insulating film 113, and the concentration of impurities in the third-3 insulating film 113 may be higher than the concentration of impurities in the third-4 insulating film 114.

Referring to FIGS. 5 and 6, in some embodiments, the slope θ11 of the side wall of the hole H in the first-1 stacked structure ST11 may be the same as the slope θ21 of the side wall of the hole H in the second-1 stacked structure ST21. The slope θ11 of the side wall of the hole H in the first-1 stacked structure ST11 may be, for example, 90 degrees. The width of the hole H in the first-1 stacked structure ST11 may be constant. For example, a first portion of the hole H may be in the first-1 stacked structure ST11 and may have side walls with the slope θ11, a second portion of the hole H may be in the first-2 stacked structure ST12 and may have side walls with the slope θ12, a third portion of the hole H may be in the second-1 stacked structure ST21 and may have side walls with the slope θ21, and a fourth portion of the hole H may be in the second-2 stacked structure ST22 and may have side walls with the slope θ22.

Referring to FIG. 5, in some embodiments, the slope θ11 of the side wall of the hole H in the first-1 stacked structure ST11 may differ from the slope θ12 of the side wall of the hole H in the first-2 stacked structure ST12. The slope of the side walls θ11 of the hole H in the first-1 stacked structure ST11 may be greater than the slope θ12 of the side wall of the hole H in the first-2 stacked structure ST12.

Referring to FIG. 6, in some embodiments, the slope θ11 of the side wall of the hole H in the first-1 stacked structure ST11 may be the same as the slope θ12 of the side wall of the hole H in the first-2 stacked structure ST12.

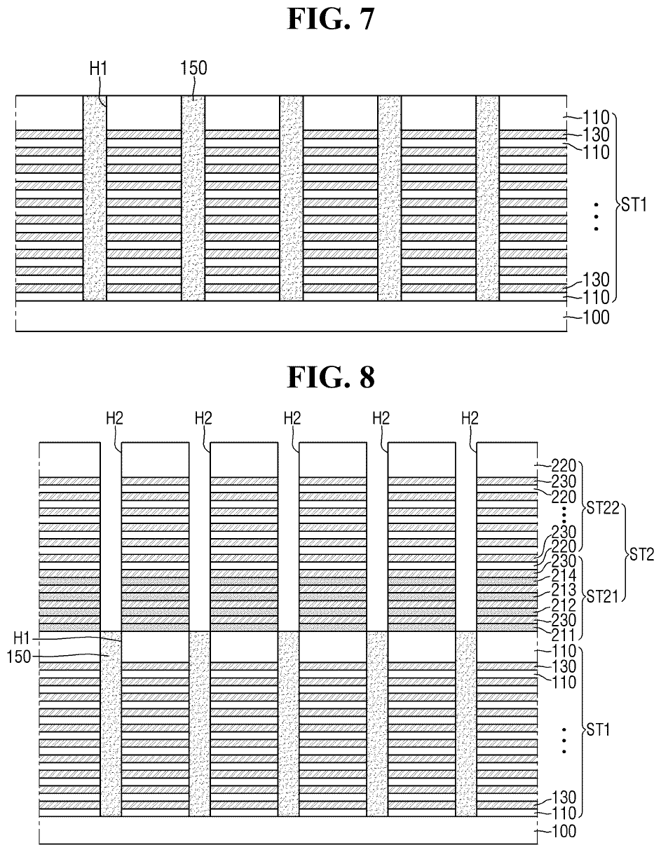

FIGS. 7 and 8 are diagrams for explaining a method for fabricating a semiconductor memory device according to some embodiments. For convenience of explanation, repeated parts of contents explained above with reference to FIGS. 1 to 6 will be briefly explained or omitted.

Referring to FIG. 7, the first stacked structure ST1 is formed on the cell substrate 100. The first hole H1 which penetrates (i.e., extends into) the first stacked structure ST1 is formed. An etchant used to form the first hole H1 may include, for example, fluorine (F) or phosphorus (P).

A sacrificial film 150 is formed in the first hole H1. The sacrificial film 150 may include, for example, polysilicon (poly Si).

Referring to FIG. 8, a second stacked structure ST2 is formed on the first stacked structure ST1. The second hole H2 which penetrates (i.e., extends into) the second stacked structure ST2 is formed. The second hole H2 is formed on the sacrificial film 150. Accordingly, referring to FIGS. 1 to 3, the hole H including the first hole H1 and the second hole H2 is formed. The sacrificial film 150 may then be removed.

Due to the fabrication process, the width of the first hole H1 and the width of the second hole H2 may decrease toward the cell substrate 100. Therefore, the width of the first hole H1 at the uppermost part of the first stacked structure ST1 may be greater than the width of the second hole H2 at the lowermost part of the second stacked structure ST2. The higher the height is of the second stacked structure ST2 (e.g., relative to the upper face of the cell substrate 100), the greater the difference between the width of the first hole H1 at the uppermost part of the first stacked structure ST1 and the width of the second hole H2 at the lowermost part of the second stacked structure ST2 may be. Accordingly, the sacrificial film 150 in the first hole HI may not be completely removed.

However, in the semiconductor memory device according to some embodiments, the first films 211, 212, 213, and 214 of the second-1 stacked structure ST21 include impurities, and the concentration of the impurities in the respective first films 211, 212, 213, and 214 increases toward the first stacked structure ST1. As the concentration of impurities doped in the first films 211, 212, 213, and 214 increases, the etching rate of the second hole H2 in the first films 211, 212, 213, and 214 may increase. For example, since the impurities in the first films 211, 212, 213, and 214 may also be included in the etchant used when forming the second hole H2, the impurities in the first films 211, 212, 213, and 214 may be supplied as etchant when forming the hole H, and thus the etching rate of the second holes H2 in the first films 211, 212, 213, and 214 including impurities may increase. Therefore, the width of the second hole H2 penetrating (i.e., extending) through the second-1 stacked structure ST21 may be constant. Also, the difference between the width of the first hole H1 at the uppermost part of the first stacked structure ST1 and the width of the second hole H2 at the lowermost part of the second stacked structure ST2 may be very small, or there may be no difference. The width of the first hole H1 at the uppermost part of the first stacked structure ST1 may be the same as the width of the second hole H2 at the lowermost part of the second stacked structure ST2. As a result, the hole H which penetrates (i.e., extends into) the plurality of stacked structures ST1 and ST2 and has side walls including no step may be formed. Therefore, removal of the sacrificial film 150 in the hole H may be facilitated. The hole H described with reference to FIGS. 1 to 8 may be applied to holes included in various semiconductor devices.

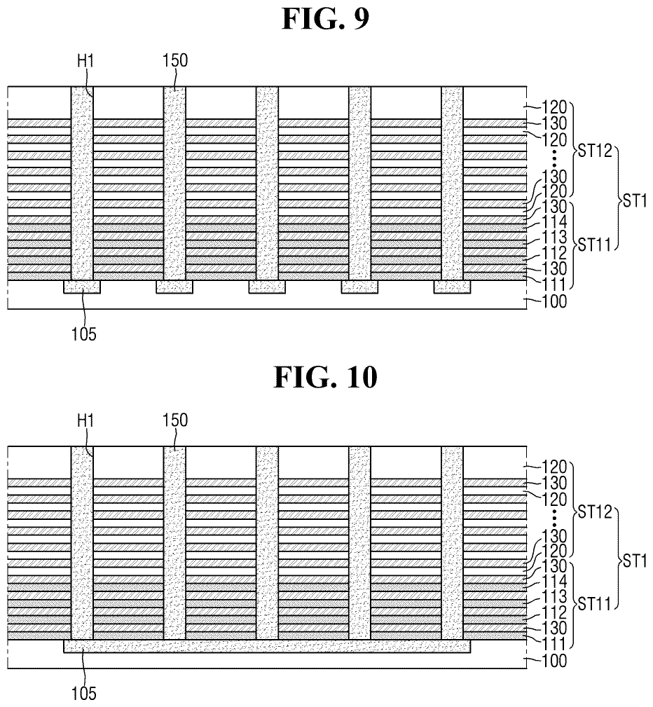

FIGS. 9 and 10 are diagrams for explaining a method for fabricating a semiconductor memory device according to some embodiments. For convenience of explanation, repeated parts of contents explained above with reference to FIGS. 1 to 8 will be briefly explained or omitted.

Referring to FIGS. 9 and 10, the cell substrate 100 may include a substrate sacrificial film 105 therein. The substrate sacrificial film 105 may include, for example, polysilicon. The first-1 stacked structure ST11 and the first-2 stacked structure ST12 are sequentially formed on the cell substrate 100. The first hole H1 which penetrates (i.e., extends into) the first-1 stacked structure ST11 and the first-2 stacked structure ST12 is formed. The first hole HI may be formed on the substrate sacrificial film 105.

Referring to FIG. 9, in some embodiments, the cell substrate 100 may include a plurality of substrate sacrificial films 105 spaced apart from each other. Each first hole H1 is formed on one of the substrate sacrificial films 105.

Referring to FIG. 10, in some embodiments, the cell substrate 100 may include a substrate sacrificial film 105 extending longitudinally (e.g., in a direction parallel to the upper face of the cell substrate 100). A plurality of first holes H1 are formed on one substrate sacrificial film 105.

Next, referring to FIGS. 4 to 6, 9, and 10, the second stacked structure ST2 is formed on the first stacked structure ST1. The second hole H2 penetrating (i.e., extending into) the second stacked structure ST2 is formed on the sacrificial film 150. As a result, the hole H including the first hole Hl and the second hole H2 is formed. After that, the sacrificial film 150 may be removed through the hole H. As shown in FIGS. 4 to 6, the substrate sacrificial film 105 in the cell substrate 100 may be removed, or may remain in the cell substrate 100.

Alternatively, as shown in FIGS. 7 and 8, the first-1 stacked structure ST11 and the first-2 stacked structure ST12 included in the first stacked structure ST1 are sequentially formed on the cell substrate 100 with no substrate sacrificial film 105 included therein, and the first hole H1 may be formed.

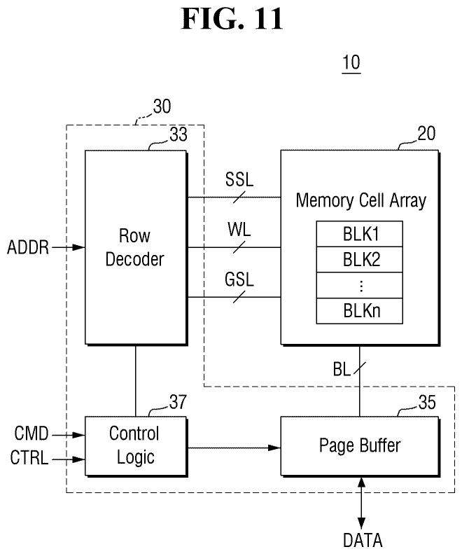

FIG. 11 is an example block diagram for explaining a semiconductor memory device according to some embodiments.

Referring to FIG. 11, the semiconductor memory device 10 according to some embodiments includes a memory cell array 20 and a peripheral circuit 30.

The memory cell array 20 may include a plurality of memory cell blocks BLK1 to BLKn. Each of the memory cell blocks BLK1 to BLKn may include a plurality of memory cells. The memory cell array 20 may be connected to the peripheral circuit 30 through a bit line BL, a word line WL, at least one string selection line SSL, and at least one ground selection line GSL. Specifically, the memory cell blocks BLK1 to BLKn may be connected to the row decoder 33 through the word line WL, the string selection line SSL, and the ground selection line GSL. Also, the memory cell blocks BLK1 to BLKn may be connected to the page buffer 35 through the bit line BL.

The peripheral circuit 30 may externally receive an address ADDR, a command CMD, and a control signal CTRL (e.g., from the outside of the semiconductor memory device 10), and may transmit and receive data DATA to and from a device that is external to the semiconductor memory device 10. The peripheral circuit 30 may include a control logic 37, a row decoder 33, and a page buffer 35. Although not shown, the peripheral circuit 30 may further include various sub-circuits such as an I/O circuit, a voltage generation circuit that generates various voltages necessary for the operation of the semiconductor memory device 10, and an error correction circuit for correcting an error of the data DATA that is read from the memory cell array 20.

The control logic 37 may be connected to the row decoder 33, the I/O circuit, and the voltage generation circuit. The control logic 37 may control the overall operation of the semiconductor memory device 10. The control logic 37 may generate various internal control signals used inside the semiconductor memory device 10 in response to the control signal CTRL. For example, the control logic 37 may adjust the voltage levels provided to the word line WL and the bit line BL, when performing a memory operation such as a program operation or an erase operation.

The row decoder 33 may select at least one of the plurality of memory cell blocks BLK1 to BLKn in response to the address ADDR, and may select at least one word line WL, at least one string selection line SSL, and at least one ground selection line GSL of the selected memory cell blocks BLK1 to BLKn. The row decoder 33 may transmit a voltage for performing the memory operation to the word line WL of the selected memory cell blocks BLK1 to BLKn.

The page buffer 35 may be connected to the memory cell array 20 through the bit lines BL. The page buffer 35 may operate as a write driver or a sense amplifier. Specifically, when performing the program operation, the page buffer 35 may operate as the write driver to apply a voltage according to the data DATA to be stored in the memory cell array 20 to the bit line BL. On the other hand, when performing the read operation, the page buffer 35 may operate as a sense amplifier to sense the data DATA stored in the memory cell array 20.

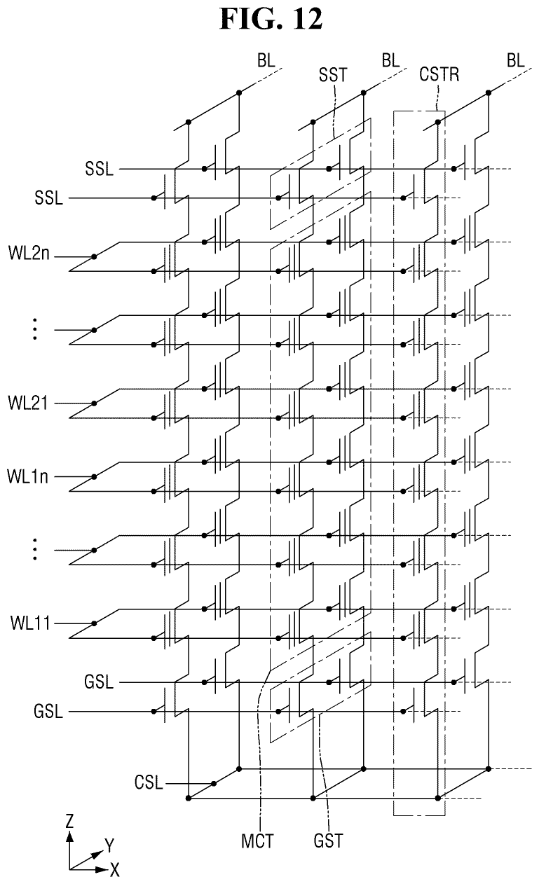

FIG. 12 is an example circuit diagram of a semiconductor memory device according to some embodiments.

Referring to FIG. 12, a memory cell array (e.g., the memory cell array 20 of FIG. 11) of the semiconductor memory device according to some embodiments may include a common source line CSL, a plurality of bit lines BL, and a plurality of cell strings CSTR.

The plurality of bit lines BL may be arranged two-dimensionally in a plane including a first direction X and a second direction Y. For example, the bit lines BL may each extend in the second direction Y, and may be spaced apart from each other and arranged along the first direction X. A plurality of cell strings CSTR may be connected in parallel to each bit line BL. The cell strings CSTR may be commonly connected to the common source line CSL. That is, a plurality of cell strings CSTR may be placed between the bit lines BL and the common source line CSL.

Each cell string CSTR may include a ground selection transistor GST connected to the common source line CSL, a string selection transistor SST connected to the bit line BL, and a plurality of memory cell transistors MCT placed between the ground selection transistor GST and the string selection transistor SST. Each memory cell transistor MCT may include a data storage element. The ground selection transistor GST, the string selection transistor SST, and the memory cell transistors MCT may be connected in series.

The common source line CSL may be commonly connected to the sources of the ground selection transistors GST. Also, a ground selection line GSL, a plurality of word lines WL11 to WL1n and WL21 to WL2n, and a string selection line SSL may be placed between the common source line CSL and the bit line BL. The ground selection line GSL may be used as a gate electrode of the ground selection transistor GST, the word lines WL11 to WL1n and WL21 to WL2n may be used as the gate electrodes of the memory cell transistors MCT, and the string selection line SSL may be used as the gate electrode of the string selection transistor SST.

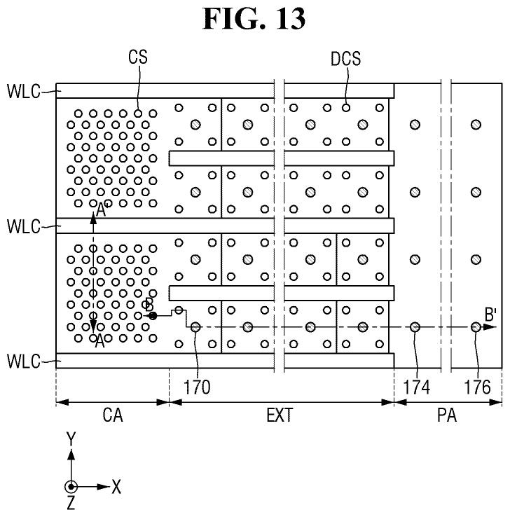

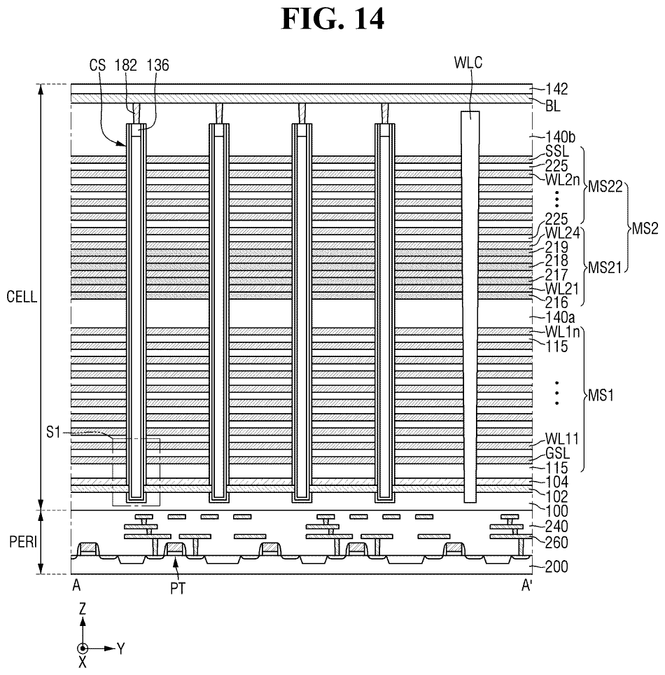

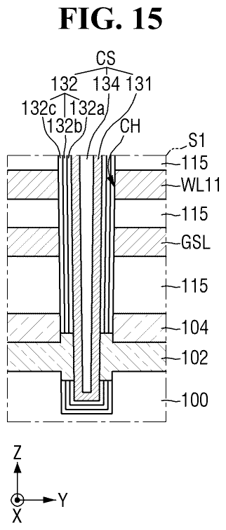

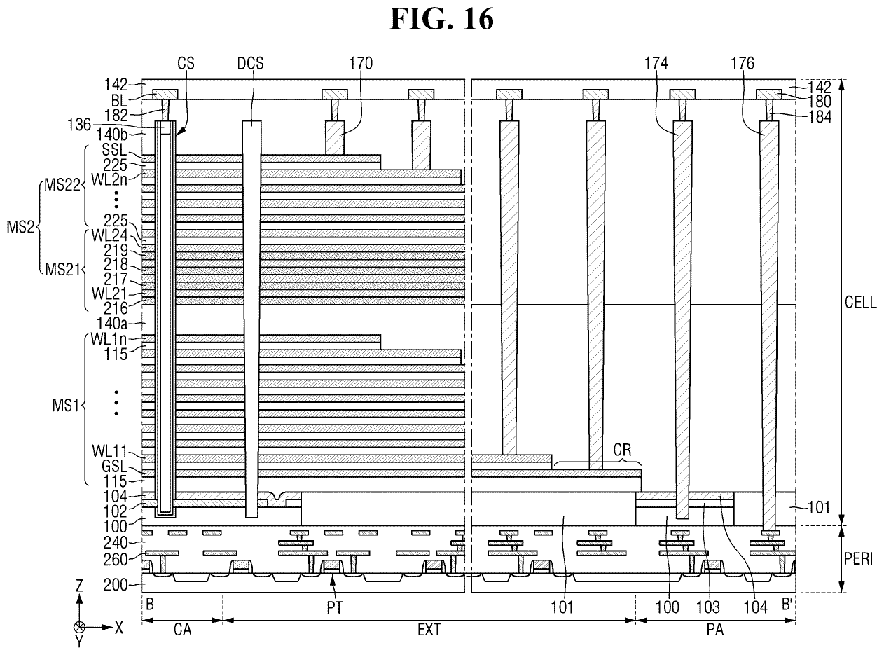

FIG. 13 is a schematic layout diagram for explaining a semiconductor memory device according to some embodiments. FIG. 14 is a cross-sectional view taken along line A-A′ of FIG. 13. FIG. 15 is an enlarged view of a region SI of FIG. 14. FIG. 16 is a cross-sectional view taken along line B-B′ of FIG. 13.

Referring to FIGS. 13 to 16, the semiconductor memory device according to some embodiments includes a cell structure CELL and a peripheral circuit structure PERI.

The cell structure CELL may include a cell substrate 100, an insulating substrate 101, mold structures MS1 and MS2, interlayer insulating films 140a and 140b, a channel structure CS, a word line cutting region WLC, a bit line BL, a cell contact 170, a source contact 174, a first I/O contact 176, a first wiring structure 180, and a bit line contact 182.

The cell substrate 100 includes a cell array region CA and an extension region EXT.

A memory cell array (e.g., the memory cell array 20 of FIG. 11) including a plurality of memory cells may be placed on the cell array region CA. For example, a channel structure CS, gate electrodes GSL, WL11 to WL1n, WL21 to WL2n, and SSL, and the like, which will be described later, may be placed on the cell array region CA. In the following description, the surface of the cell substrate 100 on which the memory cell array is placed may be referred to as a front side or an upper side (e.g., an upper face). In contrast, the surface of the cell substrate 100 opposite to the front side of the cell substrate 100 may be referred to as a back side or a lower side of the cell substrate 100.

The extension region EXT may be placed around the cell array region CA. The extension region EXT may surround the cell array region CA, for example, from a plan viewpoint. The gate electrodes GSL, WL11 to WL1n, WL21 to WL2n, and SSL may be stacked stepwise on the extension region EXT (e.g., see FIG. 16). For example, the gate electrodes GSL, WL11 to WL1n, WL21 to WL2n, and SSL may extend with different lengths in the first direction X and the second direction Y, and may have steps. Therefore, each of the gate electrodes GSL, WL11 to WL1n, WL21 to WL2n, and SSL may include a connection region CR (e.g., see FIG. 16) whose upper face is exposed on the extension region EXT. The connection region CR may be placed at the ends of the each of the gate electrodes GSL, WL11 to WL1n, WL21 to WL2n, and SSL. For example, the thickness of the gate electrodes GSL, WL11 to WL1n, WL21 to WL2n, and SSL in the connection region CR may be thicker than the thickness of the gate electrodes GSL, WL11 to WL1n, WL21 to WL2n, and SSL in the region other than the connection region CR.

The insulating substrate 101 (e.g., see FIG. 16) may be formed around the cell substrate 100. The insulating substrate 101 may form an insulating region around the cell substrate 100. The insulating substrate 101 may include, for example, but is not limited to, at least one of silicon oxide, silicon nitride, silicon oxynitride, or silicon carbide.

The lower face of the insulating substrate 101 is shown to be coplanar with the lower face of the cell substrate 100, but this is for example only. In another example, the lower face of the insulating substrate 101 may be lower than the lower face of the cell substrate 100.

In some embodiments, the cell substrate 100 and/or the insulating substrate 101 may further include a pad region PA. The pad region PA may be defined outside the extension region EXT. For example, the pad region PA may surround the extension region EXT from a plan viewpoint. The source contact 174, the first I/O contact 176, and the like may be placed in the pad region PA.

The mold structures MS1 and MS2 may be formed on the front side of the cell substrate 100. The mold structures MS1 and MS2 include a plurality of gate electrodes GSL, WL11 to WL1n, WL21 to WL2n, and SSL and a plurality of mold insulating films 115, 216, 217, 218, 219 and 225 that are stacked on the cell substrate 100. Each of the gate electrodes GSL, WL11 to WL1n, WL21 to WL2n, and SSL and each of the mold insulating films 115, 216, 217, 218, 219, and 225 may be a layered structure that extends parallel to the front side of the cell substrate 100. The gate electrodes GSL, WL11 to WL1n, WL21 to WL2n, and SSL are spaced apart from each other by the mold insulating films 115, 216, 217, 218, 219, and 225, and may be sequentially stacked on the cell substrate 100.

In some embodiments, the mold structures MS1 and MS2 may include a plurality of stacks (e.g., a first mold stack MS1 and a second mold stack MS2) stacked sequentially on the cell substrate 100. Although the number of stacks stacked on the cell substrate 100 is shown as two, this is only for convenience of explanation, and the number of stacks stacked on the cell substrate 100 may be three or more.

The first mold stack MS1 may include first gate electrodes GSL and WL11 to WL1n and a first mold insulating film 115 which are alternately stacked on the cell substrate 100. In some embodiments, the first gate electrodes GSL and WL11 to WL1n may include a ground selection line GSL and a plurality of first word lines WL11 to WL1n that are sequentially stacked on the cell substrate 100. The number and placement of the ground selection lines GSL and the first word lines WL11 to WL1n are merely exemplary, and are not limited to those shown.

The second mold stack MS2 may include a plurality of second mold insulating films 216, 217, 218, 219, and 225 and a plurality of second gate electrodes WL21 to WL2n and SSL that are alternately stacked. In some embodiments, the second gate electrodes WL21 to WL2n and SSL may include a plurality of second word lines WL21 to WL2n and a string selection line SSL that are sequentially stacked on the first mold stack MS1. The number, placement, and the like of the second word lines WL21 to WL2n and the string selection line SSL are merely exemplary, and are not limited to those shown.

The gate electrodes GSL, WL11 to WL1n, WL21 to WL2n, and SSL may each include, but are not limited to, conductive materials, for example, metal such as tungsten (W), molybdenum (Mo), ruthenium (Ru), cobalt (Co), and nickel (Ni), and a semiconductor material such as silicon. As an example, each of the gate electrodes GSL, WL11 to WL1n, WL21 to WL2n, and SSL may include at least one of tungsten (W), molybdenum (Mo), or ruthenium (Ru). As another example, the gate electrodes GSL, WL11 to WL1n, WL21 to WL2n, and SSL may each include polysilicon.

Each of the mold insulating films 115, 216, 217, 218, 219, and 225 may include, but are not limited to, an insulating material, for example, at least one of silicon oxide, silicon nitride or silicon oxynitride.

The plurality of second mold insulating films 216, 217, 218, 219, and 225 include the plurality of first insulating films 216, 217, 218, and 219 including impurities, and the plurality of second insulating films 225 including no impurities. The plurality of first insulating films 216, 217, 218, and 219 are placed between the first mold stack MS1 and the plurality of second insulating films 225. The plurality of first insulating films 216, 217, 218, and 219 may be doped with impurities. In other words, the second mold stack MS2 includes a second-1 mold stack MS21 including second gate electrodes WL21 to WL24 and the first insulating films 216, 217, 218, and 219 that are alternately stacked, and a second-2 mold stack MS22 including second gate electrodes WL25 to WL2n and SSL and second insulating films 225 that are alternately stacked. The second-1 mold stack MS21 is placed between the first mold stack MS1 and the second-2 mold stack MS22. The number of the first insulating films 216, 217, 218, and 219 and the number of the second insulating films 225 are merely exemplary, and are not limited to those shown.

Interlayer insulating films 140a and 140b may be formed on the front side of the cell substrate 100 to cover or overlap the mold structures MS1 and MS2. In some embodiments, the interlayer insulating films 140a and 140b may include a first interlayer insulating film 140a and a second interlayer insulating film 140b that are sequentially stacked on the cell substrate 100. The first interlayer insulating film 140a may cover or overlap the first mold stack MS1, and the second interlayer insulating film 140b may cover or overlap the second mold stack MS2. The interlayer insulating films 140a and 140b may each include, for example, but are not limited to, at least one of silicon oxide, silicon oxynitride, or a low dielectric constant (low-k) material having a lower dielectric constant than silicon oxide.

The channel structure CS may be formed on the cell array region CA of the cell substrate 100. The channel structure CS may extend in a vertical direction (hereinafter referred to as a third direction Z) intersecting the front side of the cell substrate 100, and may penetrate (i.e., extend into) the mold structures MS1 and MS2. For example, the third direction Z may be perpendicular to the front side (e.g., upper face) of the cell substrate 100. For example, the channel structure CS may have a pillar shape (e.g., a cylindrical shape) extending in the third direction Z. Therefore, the channel structure CS may intersect the plurality of gate electrodes GSL, WL11 to WL1n, WL21 to WL2n, and SSL.

In some embodiments, the plurality of channel structures CS may be arranged in the form of a zigzag (e.g., see FIG. 13). For example, the plurality of channel structures CS may be arranged alternately in the first direction X and the second direction Y. The plurality of channel structures CS arranged in the form of a zigzag may further improve the degree of integration of the semiconductor memory device. In some embodiments, the plurality of channel structures CS may be arranged in the form of a honeycomb.

The channel structure CS may include a semiconductor pattern 131 and an information storage film 132 (e.g., see FIG. 15).

The semiconductor pattern 131 may extend in the third direction Z and penetrate (i.e., extend into) the mold structures MS1 and MS2. Although the semiconductor pattern 131 is shown to have a cup shape (e.g., a U shape), this is only an example. For example, the semiconductor pattern 131 may have various shapes such as a cylindrical shape, a rectangular barrel shape, and a solid filler shape. The semiconductor pattern 131 may include, for example, but is not limited to, a semiconductor material such as single crystal silicon, polycrystalline silicon, organic semiconductor substance, and carbon nanostructure.

The information storage film 132 may be interposed between the semiconductor pattern 131 and each of the gate electrodes GSL, WL11 to WL1n, WL21 to WL2n, and SSL. For example, the information storage film 132 may extend along the outer side face (i.e., outer side wall) of the semiconductor pattern 131.

In some embodiments, the information storage film 132 may be formed of multiple films. For example, the information storage film 132 may include a tunnel insulating film 132a, a charge storage film 132b, and a blocking insulating film 132c which are sequentially stacked on the outer side face of the semiconductor pattern 131.

The tunnel insulating film 132a may include, for example, silicon oxide or a high dielectric constant material having a higher dielectric constant than silicon oxide (e.g., aluminum oxide (Al₂O₃) and hafnium oxide (HfO₂)). The charge storage film 132b may include, for example, silicon nitride. The blocking insulating film 132c may include, for example, silicon oxide or a high dielectric constant material having a higher dielectric constant than silicon oxide (e.g., aluminum oxide (Al₂O₃), and hafnium oxide (HfO₂)).

In some embodiments, the channel structure CS may further include a filling pattern 134. For example, the channel structure CS may also include a channel hole CH extending in the third direction Z and penetrating (i.e., extending into) the mold structures MS1 and MS2. The information storage film 132, the semiconductor pattern 131, and the filling pattern 134 may be sequentially stacked inside the channel hole CH. The information storage film 132 and the semiconductor pattern 131 may each extend conformally along the profile of the channel hole CH. The filling pattern 134 may fill a region of the channel hole CH that remains after the information storage film 132 and the semiconductor pattern 131 are filled.

In some embodiments, the channel structure CS may further include a channel pad 136 (e.g., sec FIGS. 14 and 16). The channel pad 136 may be formed to be connected to the semiconductor pattern 131. For example, the channel pad 136 may be formed in the second interlayer insulating film 140b, and may be connected to the upper part of the semiconductor pattern 131. The channel pad 136 may include, for example, but is not limited to, impurity-doped polysilicon.

Each of the first mold stack MS1 and the first interlayer insulating film 140a, the first mold insulating film 115 and the first interlayer insulating film 140a, the second-1 mold stack MS21, the first insulating films 216, 217, 218, and 219, the second-2 mold stack MS22 and the second interlayer insulating film 140b, the second insulating film 225 and the second interlayer insulating film 140b, and the channel hole CH may correspond to each of the first stacked structure ST1, the first interlayer insulating film 110, the second-1 stacked structure ST21, the first films 211, 212, 213, and 214, the second-2 stacked structure ST22, the second film 220, and the hole H of FIGS. 1 to 3. For example, the first mold stack MS1 and the first interlayer insulating film 140a may correspond to the first stacked structure ST1 of FIGS. 1 to 3, the first mold insulating film 115 and the first interlayer insulating film 140a may correspond to the first interlayer insulating film 110 of FIGS. 1 to 3, the second-1 mold stack MS21 may correspond to the second-1 stacked structure ST21 of FIGS. 1 to 3, the first insulating films 216, 217, 218, and 219 may correspond to the first films 211, 212, 213, and 214 of FIGS. 1 to 3, the second-2 mold stack MS22 and the second interlayer insulating film 140b may correspond to the second-2 stacked structure ST22 of FIGS. 1 to 3, the second insulating film 225 and the second interlayer insulating film 140b may correspond to the second film 220 of FIGS. 1 to 3, and the channel hole CH may correspond the hole H of FIGS. 1 to 3.

For example, the first insulating films 216, 217, 218, and 219 and the second insulating film 225 may include silicon oxide. The first insulating films 216, 217, 218 and 219 may be doped with impurities, and the second insulating film 225 may not be doped with impurities (e.g., may be free of impurities). The impurities may be, for example, any one of fluorine (F) and phosphorus (P). The concentration of impurities in each of the first insulating films 216, 217, 218 and 219 may be different. The concentration of impurities in each of the first insulating films 216, 217, 218, and 219 may increase (for example, gradually) toward the first mold stack MS1. For example, the concentration of impurities in the first-1 insulating film 216 may be higher than the concentration of impurities in the first-2 insulating film 217, the concentration of impurities in the first-2 insulating film 217 may be higher concentration of impurities in the first-3 insulating film 218, and the concentration of impurities in the first-3 insulating film 218 may be higher than the concentration of impurities in the first-4 insulating film 219.

The channel hole CH may extend in the third direction Z inside the mold structures MS1 and MS2. The channel hole CH may penetrate (i.e., extend into) the mold structures MS1 and MS2. The side wall of the channel hole CH may not include a step. That is, the side wall of the channel hole CH may be free of a step or, said another way, may be free of a stepped portion. For example, the side wall of the channel hole CH may not have a stepped profile. The width of the channel hole CH at the uppermost part of the first mold stack MS1 may be substantially the same as the width of the channel hole CH at the lowermost part of the second mold stack MS2 (e.g., the lowermost part of the second-1 mold stack MS21).

The channel hole CH may include portions in which the slopes of the side walls are different from each other.

In some embodiments, as shown in FIGS. 2 and 3, the slope of the side walls of the channel hole CH in the second-1 mold stack MS21 may be greater than the slope of the side walls of the channel hole CH in the first mold stack MS1.

In some embodiments, as shown in FIG. 2, the slope of the side walls of the channel hole CH in the second-1 mold stack MS21 may be different from the slope of the side walls of the channel hole CH in the second-2 mold stack MS22. The slope of the side walls of the channel hole CH in the second-1 mold stack MS21 may be greater than the slope of the side walls of the channel hole CH in the second-2 mold stack MS22.

In some embodiments, as shown in FIG. 3, the slope of the side walls of the channel hole CH in the second-1 mold stack MS21 may be the same as the slope of the side walls of the channel hole CH in the second-2 mold stack MS22. The width of the channel hole CH in the second mold stack MS2 may be constant. The slope of the side walls of the channel hole CH in the second-2 mold stack MS22 may be greater than the slope of the side walls of the channel hole CH in the first mold stack MS1.

The channel structure CS is formed in the channel hole CH. For example, the channel structure CS may include the channel hole CH, the semiconductor pattern 131, the information storage film 132, and the filling pattern 134. Accordingly, the channel structure CS does not have a bent part (e.g., a step) between the first mold stack MS1 and the second mold stack MS2. If the channel structure CS includes the bent part, the characteristics of the memory cell may be degraded or made non-uniform. However, since the channel structure CS according to some embodiments does not include the bent part, the characteristics of the memory cell may be improved or made uniform.

In some embodiments, the dummy channel structure DCS may be placed inside the mold structures MS1 and MS2 of the extension region EXT. The dummy channel structure DCS may, for example, have a shape similar to the channel structure CS. In some embodiments, the dummy channel structure DCS may not have a bent part (e.g., a step) between the first mold stack MS1 and the second mold stack MS2. In some other embodiments, the dummy channel structure DCS may have a bent part between the first mold stack MS1 and the second mold stack MS2.

In some embodiments, the size of the dummy channel structure DCS may differ from the size of the channel structure CS. In some other embodiments, the size of the dummy channel structure DCS may be the same as the size of the channel structure CS. In some embodiments, the dummy channel structure DCS may be made up of the same film quality as that of the channel structure CS. For example, the dummy channel structure DCS may include a semiconductor pattern 131 and an information storage film 132, similarly to the channel structure CS. In some other embodiments, the dummy channel structure DCS may be made up of a film quality different from the channel structure CS. For example, the dummy channel structure DCS may include a film different from the channel structure CS.

In some embodiments, the source layer 102 may be formed on the cell substrate 100. The source layer 102 may be interposed between the cell substrate 100 and the mold structures MS1 and MS2. For example, the source layer 102 may conformally extend along the upper face of the cell substrate 100. In some embodiments, the source layer 102 may be formed on the cell array region CA, and may not be formed on the extension region EXT, but is not limited thereto.

The source layer 102 may be connected to the semiconductor pattern 131 of cach channel structure CS. For example, the source layer 102 may penetrate (i.e., extend into) the information storage film 132 and come into contact with the side face of the semiconductor pattern 131. Such a source layer 102 may be provided as a common source line (e.g., the common source line CSL of FIG. 12) of the semiconductor memory device. The source layer 102 may include, but is not limited to, a conductive material, for example, doped polysilicon or metal.

In some embodiments, a part of the source layer 102 adjacent to the semiconductor pattern 131 may have a form that protrudes toward the information storage film 132. For example, in a region adjacent to the semiconductor pattern 131, the length of the source layer 102 extending in the third direction Z may further increase.

In some embodiments, the channel structure CS may penetrate (i.e., extend into) the source layer 102. For example, the lower part of the channel structure CS may be placed in the cell substrate 100 under the source layer 102.

Although not shown, a base insulating film may be interposed between the cell substrate 100 and the source layer 102. The base insulating film may include, for example, but is not limited to, at least one of silicon oxide, silicon nitride or silicon oxynitride.

The source sacrificial film 103 may be formed on the extension region EXT and/or the pad region PA of the cell substrate 100. The source sacrificial film 103 may be interposed between the cell substrate 100 and the mold structures MS1 and MS2. For example, the source sacrificial film 103 may extend conformally along the upper face of the cell substrate 100. In some embodiments, the source sacrificial film 103 may be formed on the extension region EXT and/or the pad region PA, and may not be formed on the cell array region CA.

The source sacrificial film 103 may be placed at the same level as the source layer 102. In this specification, the expression “placed at the same level” means placement at the same height on the basis of the upper face of the cell substrate 100. For example, the term “level” may refer to a height in the third direction Z (e.g., a vertical direction) from the upper face of the cell substrate 100. For example, the lower face of the source sacrificial film 103 may be placed at the same height as the lower face of the source layer 102.

In some embodiments, the source layer 102 and/or the source sacrificial film 103 may not be formed on the insulating substrate 101. Although not specifically shown, the upper face of the insulating substrate 101 may be coplanar with the upper face of the source layer 102 and/or the upper face of the source sacrificial film 103. As another example, the upper face of the insulating substrate 101 may be formed to be higher than the upper face of the source layer 102 and/or the upper face of the source sacrificial film 103, as shown in FIG. 16.

The source sacrificial film 103 may be a layer that remains after a part thereof is replaced with the source layer 102. In this case, the thickness of the source layer 102 may be the same as the thickness of the source sacrificial film 103. In this specification, the term “same” means not only exactly the same thing, but also includes minute differences that may occur due to process margins and the like. For example, the upper face of the source sacrificial film 103 may be placed at the same height as the upper face of the source layer 102.

The source sacrificial film 103 may include an insulating material, for example, but is not limited to, at least one of silicon oxide, silicon nitride, or silicon oxynitride. In some embodiments, the source sacrificial film 103 may include a material that has an etching selectivity with respect to the mold insulating films 115, 216, 217, 218, 219, and 225. As an example, cach of the mold insulating films 115, 216, 217, 218, 219, and 225 may include silicon oxide, and the source sacrificial film 103 may include silicon nitride.

A support layer 104 may be formed on the cell substrate 100, the source layer 102 and the source sacrificial film 103. The support layer 104 may be interposed between the source layer 102 and the mold structures MS1 and MS2, and between the source sacrificial film 103 and the mold structures MS1 and MS2. For example, the support layer 104 may extend conformally along the upper face of the cell substrate 100, the upper face of the source layer 102, and the upper face of the source sacrificial film 103.

The support layer 104 may include a material having an etching selectivity with respect to the source sacrificial film 103. As an example, the source sacrificial film 103 may include a silicon nitride film, and the support layer 104 may include a polysilicon film.

The support layer 104 may be used as a support for preventing the mold stack from collapsing or falling in a replacement process for forming the source layer 102. For example, the source layer 102 and/or the source sacrificial film 103 may expose a part of the upper face of the cell substrate 100, and a part of the support layer 104 may extend along the upper face of the exposed cell substrate 100 to come into contact with the upper face of the cell substrate 100.

The word line cutting region WLC may extend in the first direction X to cut the mold structures MS1 and MS2. The mold structures MS1 and MS2 may be divided by the word line cutting region WLC to form a plurality of memory cell blocks (e.g., the plurality of memory cell blocks BLK1 to BLKn of FIG. 11). The word line cutting region WLC may include an insulating material, for example, but is not limited to, at least one of silicon oxide, silicon nitride or silicon oxynitride.

A plurality of word line cutting regions WLC may be arranged two-dimensionally in a plane including the first direction X and the second direction Y. For example, the word line cutting regions WLC may each extend in the first direction X, and may be spaced apart from each other and arranged along the second direction Y.

The bit line BL may be formed on the mold structures MS1 and MS2. The bit line BL may extend in the second direction Y and may be connected to a plurality of channel structures CS arranged along the second direction Y. For example, a bit line contact 182 connected to the channel pad 136 may be formed inside the second interlayer insulating film 140b. The bit line BL may be electrically connected to the channel structure CS through the bit line contact 182.

The plurality of bit lines BL may be arranged two-dimensionally inside a plane including the first direction X and the second direction Y. For example, the bit lines BL may cach extend in the second direction Y, and may be spaced apart from each other and arranged along the first direction X.

The cell contact 170 may be placed on the extension region EXT. The cell contact 170 may be electrically connected to each of the gate electrodes GSL, WL11 to WL1n, WL21 to WL2n, and SSL. In some embodiments, the lower face of each cell contact 170 may come into contact with the connection regions CR of the respective gate electrodes GSL, WL11 to WL1n, WL21 to WL2n, and SSL (e.g., see FIG. 16). Accordingly, the cell contact 170 may be electrically connected to the gate electrodes GSL, WL11 to WL1n, WL21 to WL2n, and SSL placed at the uppermost part, and may be electrically separated from the remaining gate electrodes except the gate electrode placed at the uppermost part. For example, the lower face of the cell contact 170 may be placed inside each of the gate electrodes GSL, WL11 to WL1n, WL21 to WL2n, and SSL.

The source contact 174 may be placed on the pad region PA. The source contact 174 may be electrically connected to the source layer 102. For example, the source contact 174 may extend in the third direction Z to penetrate (i.e., extend into) the interlayer insulating films 140a and 140b, and may be electrically connected to the cell substrate 100. In some other embodiments, the source contact 174 may be omitted.

A first I/O contact 176 may be placed on the pad region PA. The first I/O contact 176 may be electrically connected to the second wiring structure 260. The first I/O contact 176, for example, may extend in the third direction Z, penetrate (i.e., extend into) the interlayer insulating films 140a and 140b and the insulating substrate 101, and be electrically connected to the second wiring structure 260.

The first wiring structure 180 may be connected to the cell contact 170, the source contact 174 and the first I/O contact 176. For example, a first inter-wiring insulating film 142 that covers or overlaps the second interlayer insulating film 140b may be formed. The first wiring structure 180 may be formed in the first inter-wiring insulating film 142. A contact via 184 may be formed in the second interlayer insulating film 140b. The first wiring structure 180 may be electrically connected to each of the cell contact 170, the source contact 174, and the first I/O contact 176 through the contact via 184. Although not specifically shown, the first wiring structure 180 may also be connected to the bit line BL.

The peripheral circuit structure PERI may include a peripheral circuit board 200 (also referred to as a peripheral circuit substrate 200), a peripheral circuit element PT, and a second wiring structure 260.

The peripheral circuit substrate 200 may include, for example, a semiconductor

substrate such as a silicon substrate, a germanium substrate or a silicon-germanium substrate. As another example, the peripheral circuit substrate 200 may include a silicon-on-insulator (SOI) substrate or a germanium-on-insulator (GOI) substrate.

The peripheral circuit element PT may be formed on the peripheral circuit board 200. The peripheral circuit element PT may constitute a peripheral circuit (e.g., the peripheral circuit 30 of FIG. 11) that controls the operation of the semiconductor memory device. For example, the peripheral circuit element PT may include control logic (e.g., the control logic 37 of FIG. 11), a row decoder (e.g., the row decoder 33 of FIG. 11), a page buffer (e.g., the page buffer 35 of FIG. 11), and the like. In the following description, the surface of the peripheral circuit board 200 on which the peripheral circuit elements PT are placed may be referred to as a front side of the peripheral circuit board 200. Conversely, the surface of the peripheral circuit board 200 opposite to the front side of the peripheral circuit board 200 may be referred to as a back side of the peripheral circuit board 200.

The peripheral circuit element PT may include, for example, but is not limited to, a transistor. For example, the peripheral circuit element PT may include not only various active elements such as a transistor, but also various passive elements such as a capacitor, a resistor, and an inductor.

In some embodiments, the back side of the cell substrate 100 may be opposite to the front side of the peripheral circuit substrate 200. For example, the second inter-wiring insulating film 240 that covers the peripheral circuit elements PT may be formed on the front side of the peripheral circuit substrate 200. The cell substrate 100 and/or the insulating substrate 101 may be stacked on the upper face of the second inter-wiring insulating film 240.

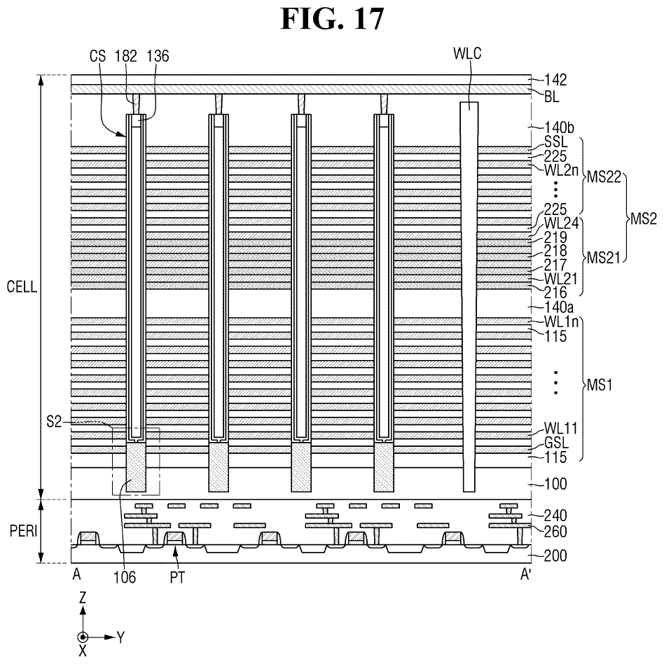

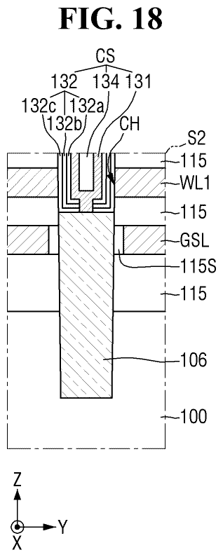

FIG. 17 is a diagram for explaining a semiconductor memory device according to some embodiments. FIG. 18 is an enlarged view of a region S2 of FIG. 17. In particular, FIG. 17 is a cross-sectional view taken along line A-A′ of FIG. 13. For convenience of explanation, repeated parts of contents explained above with reference to FIGS. 1 to 16 will be briefly explained or omitted.

Referring to FIGS. 17 and 18, a semiconductor memory device according to some embodiments includes a source pattern 106.

The source pattern 106 may be formed on the cell substrate 100. The source pattern 106 may be connected to the semiconductor pattern 131 of the channel structure CS. For example, the semiconductor pattern 131 may penetrate (i.e., extend into) the information storage film 132 and come into contact with the upper face of the source pattern 106. The source pattern 106 and the cell substrate 100 may be provided as a common source line (e.g., the common source line CSL of FIG. 12) of the semiconductor memory device.

The source pattern 106 may include a conductive material, for example, but is not limited to, impurity-doped polysilicon or metal. The source pattern 106 may be formed from the cell substrate 100, for example, but is not limited to, by a selective epitaxial growth.

The lower part of the source pattern 106 is shown as being embedded in the cell substrate 100, but this is for example only. As another example, the lower face of the source pattern 106 may be coplanar with the upper face of the cell substrate 100.

In some embodiments, the upper face of the source pattern 106 may intersect some of the gate electrodes GSL, WL11 to WL1n, WL21 to WL2n, and SSL. As an example, the upper face of the source pattern 106 may be formed to be higher than the upper face of the ground selection line GSL. In this case, the gate insulating film 115S may be interposed between the gate electrode (e.g., the ground selection line GSL) intersecting the source pattern 106 and the source pattern 106.

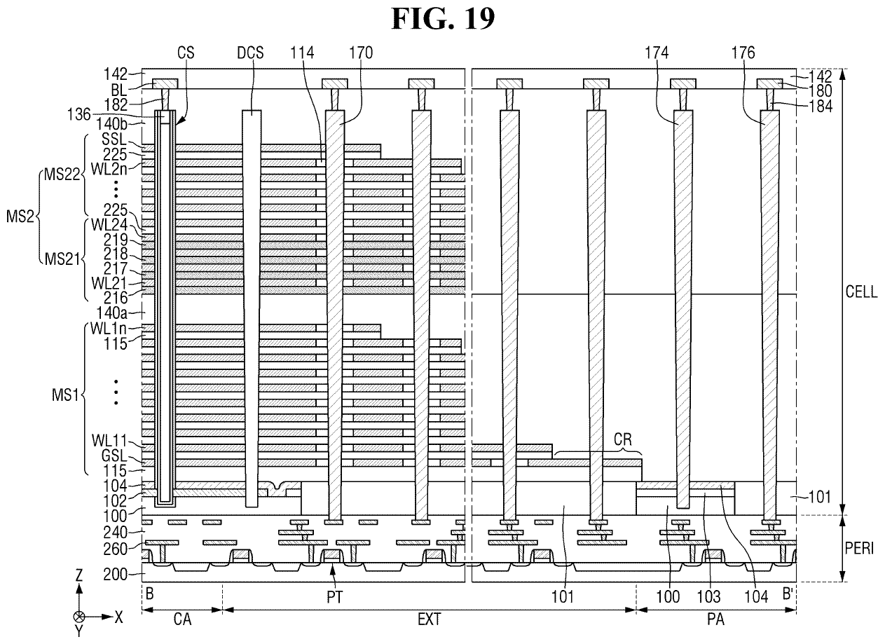

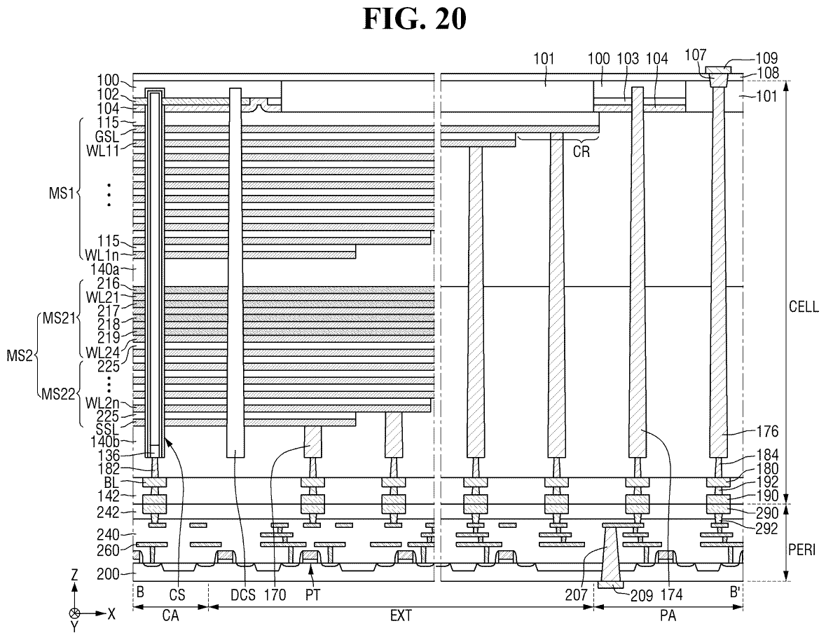

FIGS. 19 and 20 are diagrams for explaining a semiconductor memory device according to some embodiments. In particular, FIGS. 19 and 20 are cross-sectional views taken along line B-B′ of FIG. 13. For convenience of explanation, repeated parts of contents explained above with reference to FIGS. 1 to 16 will be briefly explained or omitted.

Referring to FIG. 19, in the semiconductor memory device according to some embodiments, the cell contact 170 may extend in the third direction Z and penetrate (i.e., extend into) the mold structures MS1 and MS2 on the extension region EXT. The cell contact 170 may be electrically connected to each of the gate electrodes GSL, WL11 to WL1n, WL21 to WL2n and SSL through the connection region CR. For example, the cell contact 170 may penetrate (i.e., extend into) the connection region CR, and the side faces of the cell contact 170 may be in contact with the inner side face of the connection region CR. For example, the lower face of the cell contact 170 may be placed inside the insulating substrate 101. In some embodiments, the thickness of the connection region CR may be thicker than the thickness of other gate electrodes placed thereunder.

The insulating pattern 124 may be placed between the cell contact 170 and the mold structures MS1 and MS2. The insulating pattern 124 may be placed between the cell contact 170 and the gate electrodes GSL, WL11 to WL1n, WL21 to WL2n, and SSL other than the connection region CR. The insulating pattern 124 may be placed between the cell contact 170 and the gate electrodes GSL, WL11 to WL1n, WL21 to WL2n, and SSL whose upper faces are not exposed. As an example, the insulating pattern 124 may be an annular structure that surrounds the side faces of the cell contact 170. Accordingly, the cell contact 170 may be electrically connected to the gate electrodes GSL, WL11 to WL1n, WL21 to WL2n and SSL placed at the uppermost part (e.g., the uppermost part of the mold structures MS1 and MS2), and may be electrically separated from the remaining gate electrodes except the gate electrode placed at the uppermost part.

The insulating pattern 124 may include an insulating material, for example, at least one of silicon oxide, silicon nitride, or silicon oxynitride.

Referring to FIG. 20, the front side of the cell substrate 100 is opposite to the front side of the peripheral circuit board 200 in the semiconductor memory device according to some embodiments.

For example, the semiconductor memory device according to some embodiments may be a C2C (chip-to-chip) structure. The C2C structure may mean a structure in which an upper chip including a memory cell structure CELL is manufactured on a first wafer (e.g., the cell substrate 100), and a lower chip including a peripheral circuit structure PERI is manufactured on a second wafer (e.g., the peripheral circuit substrate 200) different from the first wafer, and then, the upper chip and the lower chip are connected to each other by a bonding way.

As an example, the bonding way may mean a way of electrically connecting a first bonding metal 190 formed on the uppermost metal layer of the upper chip and a second bonding metal 290 formed on the uppermost metal layer of the lower chip. For example, when the first bonding metal 190 and the second bonding metal 290 are formed of copper (Cu), the bonding type may be a Cu—Cu bonding type. However, this is for example only, and the first bonding metal 190 and the second bonding metal 290 may, of course, be formed of various other metals such as aluminum (Al) or tungsten (W).

As the first bonding metal 190 and the second bonding metal 290 are bonded, the first wiring structure 180 may be connected to the second wiring structure 260. The first wiring structure 180 may be electrically connected to the first bonding metal 190 through the first bonding via 192. The second wiring structure 260 may be electrically connected to the second bonding metal 290 through the second bonding via 292.

The cell insulating film 108 may be placed on the back side of the cell substrate 100. The first I/O pad 109 may be placed on the cell insulating film 108. The first I/O pad 109 may be electrically connected to the peripheral circuit structure PERI through the first I/O contact 176. For example, the contact 107 may penetrate (i.e., extend) through at least a part of the cell insulating film 108 and the insulating substrate 101. The first I/O pad 109 may be electrically connected to the first I/O contact 176 through the contact 107. In some other embodiments, the contact 107 may be omitted.

The second I/O pad 209 may be placed on the back side of the peripheral circuit board 200. The second I/O pad 209 may be electrically connected to at least one of the peripheral circuit elements PT placed in the peripheral circuit structure PERI through the second I/O contact 207. Although not specifically shown, in some embodiments, the second I/O pad 209 may be electrically separated from the peripheral circuit board 200 by a peripheral circuit insulating film. For example, the peripheral circuit insulating film may be placed on the back side of the peripheral circuit board 200 between the peripheral circuit board 200 and the second I/O pad 209.

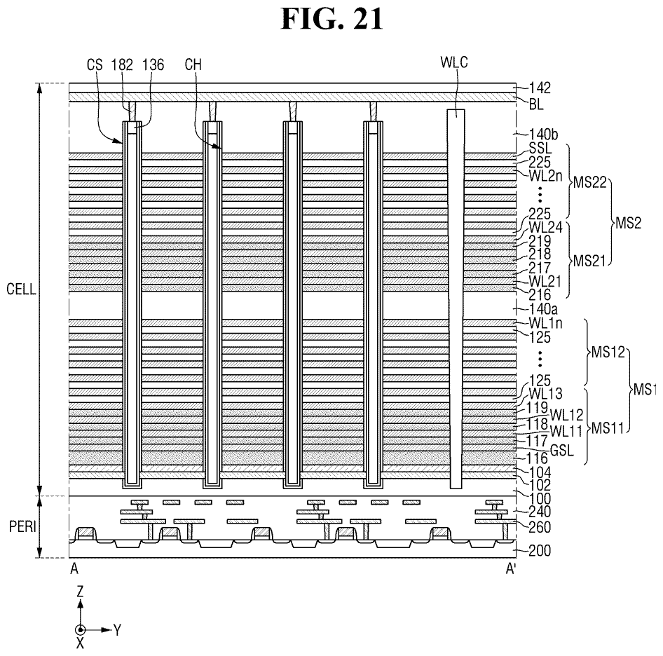

FIG. 21 is a diagram for explaining a semiconductor memory device according to some embodiments. In particular, FIG. 21 is a cross-sectional view taken along A-A′ of FIG. 13. For convenience of explanation, repeated parts of contents explained above with reference to FIGS. 1 to 16 will be briefly explained or omitted.

Referring to FIG. 21, in the semiconductor memory device according to some embodiments, the first mold stack MS1 may include first gate electrodes GSL, WL11 to WL1n and the first mold insulating films 116, 117, 118, 119, and 125 that are alternately stacked on the cell substrate 100. The first mold insulating films 116, 117, 118, 119 and 125 include a plurality of third insulating films 116, 117, 118 and 119 including impurities, and a plurality of fourth insulating films 125 including no impurities. That is, the third insulating films 116, 117, 118 and 119 may include impurities, and the plurality of fourth insulating films 125 may be free of impurities. The plurality of fourth insulating films 125 are placed between the plurality of third insulating films 116, 117, 118, and 119 and the second mold stack MS2. The plurality of third insulating films 116, 117, 118 and 119 may be doped with impurities. In other words, the first mold stack MS1 includes a first-1 mold stack MS11 including the first gate electrodes GSL and WL11 to WL13 and the third insulating films 116, 117, 118, and 119 that are alternately stacked, and a first-2 mold stack MS12 including the first gate electrodes WL14 to WL1n and the fourth insulating film 125 that are alternately stacked. The number of the third insulating films 116, 117, 118, and 119 and the number of the fourth insulating films 125 are merely exemplary and are not limited to those shown.

Each of the first-1 mold stack MS11, the third insulating films 116, 117, 118, and 119, the first-2 mold stack MS12 and the first interlayer insulating film 140a, the fourth insulating film 125 and the first interlayer insulating film 140a, the second-1 mold stack MS21, the first insulating films 216, 217, 218, and 219, the second-2 mold stack MS22 and the second interlayer insulating film 140b, the second insulating film 225 and the second interlayer insulating film 140b, and the channel hole CH may correspond to each of the first-1 stacked structure ST11, the third films 111, 112, 113, and 114, the first-2 stacked structure ST12, the fourth film 120, the second-1 stacked structure ST21, the first films 211, 212, 213, and 214, the second-2 stacked structure ST22, the second film 220, and the hole H of FIGS. 4 to 6. For example, the first-1 mold stack MS11 may correspond to the first-1 stacked structure ST11 of FIGS. 4 to 6, the third insulating films 116, 117, 118, and 119 may correspond to the third films 111, 112, 113, and 114 of FIGS. 4 to 6, the first-2 mold stack MS12 and the first interlayer insulating film 140a may correspond to the first-2 stacked structure ST12 of FIGS. 4 to 6, the fourth insulating film 125 and the first interlayer insulating film 140a may correspond to the fourth film 120 of FIGS. 4 to 6, the second-1 mold stack MS21 may correspond to the second-1 stacked structure ST21 of FIGS. 4 to 6, the first insulating films 216, 217, 218, and 219 may correspond to the first films 211, 212, 213, and 214 of FIGS. 4 to 6, the second-2 mold stack MS22 and the second interlayer insulating film 140b may correspond to the second-2 stacked structure ST22 of FIGS. 4 to 6, the second insulating film 225 and the second interlayer insulating film 140b may correspond to the second film 220 of FIGS. 4 to 6, and the channel hole CH (e.g., included in the channel structure CS) may correspond to the hole H of FIGS. 4 to 6.

For example, the third insulating films 116, 117, 118, and 119 and the fourth insulating film 125 may include silicon oxide. The third insulating films 116, 117, 118 and 119 may be doped with impurities, and the fourth insulating film 125 may not be doped with impurities. The impurities may be, for example, any one of fluorine (F) and phosphorus (P). The concentration of impurities in each of the third insulating films 116, 117, 118 and 119 may be different. The concentration of impurities in each of the third insulating films 116, 117, 118, and 119 may increase (for example, gradually) toward the cell substrate 100. For example, the concentration of impurities in the third-1 insulating film 116 may be higher than the concentration of impurities in the third-2 insulating film 117, the concentration of impurities in the third-2 insulating film 117 may be higher than the concentration of impurities in the third-3 insulating film 118, and the concentration of impurities in the third-3 insulating film 118 may be higher than the concentration of impurities in the third-4 insulating film 119.

In some embodiments, as shown in FIGS. 5 and 6, the slope of the side walls of the channel hole CH in the first-1 mold stack MS11 may be the same as the slope of the side wall of the channel hole CH in the second-1 mold stack MS21.

In some embodiments, as shown in FIG. 5, the slope of the side walls of the channel hole CH in the first-1 mold stack MS11 may be different from the slope of the side walls of the channel hole CH in the first-2 mold stack MS12. The slope of the side walls of the channel hole CH in the first-1 mold stack MS11 may be greater than the slope of the side walls of the channel hole CH in the first-2 mold stack MS12.

In some embodiments, as shown in FIG. 6, the slope of the side walls of the channel hole CH in the second-1 mold stack MS21 may be the same as the slope of the side walls of the channel hole CH in the second-2 mold stack MS22.

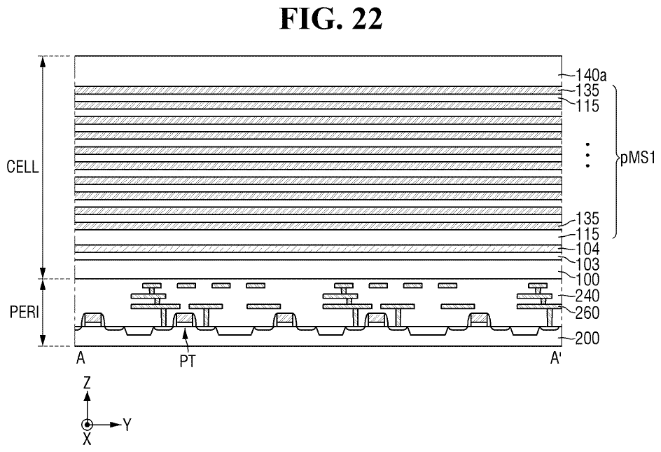

FIGS. 22 to 24 are intermediate step diagrams for explaining the method for fabricating a semiconductor memory device according to some embodiments. In particular, FIGS. 22 to 24 are cross-sectional views taken along line A-A′ of FIG. 13. For convenience of explanation, repeated parts of contents explained above with reference to FIGS. 1 to 16 will be briefly explained or omitted.

Referring to FIG. 22, a first preliminary mold pMS1 and a first interlayer insulating film 140a are formed on the cell substrate 100 and/or the insulating substrate 101.

The first preliminary mold pMS1 may be formed on the front side of the cell substrate 100. The first preliminary mold pMS1 may include a plurality of first mold sacrificial films 135 and a plurality of first mold insulating films 115 that are alternately stacked on the cell substrate 100. The first mold sacrificial films 135 may be stacked stepwise in the extension region EXT (e.g., see FIGS. 13 and 16). For example, the first preliminary mold pMS1 of the extension region EXT may be patterned stepwise. Accordingly, each first mold sacrificial film 135 of the first preliminary mold pMS1 may include a connection region CR exposed from other first mold sacrificial films 135 (e.g., see FIG. 16). Subsequently, a first interlayer insulating film 140a that covers or overlaps the first preliminary mold pMS1 may be formed.

The first mold sacrificial film 135 may include a material having an etching selectivity with respect to the first mold insulating film 115. As an example, the first mold insulating film 115 may include silicon oxide, and the first mold sacrificial film 135 may include silicon nitride.

The cell substrate 100 and/or the insulating substrate 101 may be stacked on the peripheral circuit structure PERI. For example, the peripheral circuit element PT, the second wiring structure 260 and the second inter-wiring insulating film 240 may be formed on the peripheral circuit substrate 200. The cell substrate 100 and/or the insulating substrate 101 may be stacked on the second inter-wiring insulating film 240.

In some embodiments, the source sacrificial film 103 and the source layer 102 may be formed on the cell substrate 100 before forming the first preliminary mold pMS1. The source sacrificial film 103 may include a material having an etching selectivity with respect to the first mold insulating film 115. The source layer 102 may include, but is not limited to, polysilicon doped with impurities or polysilicon doped with no impurities.

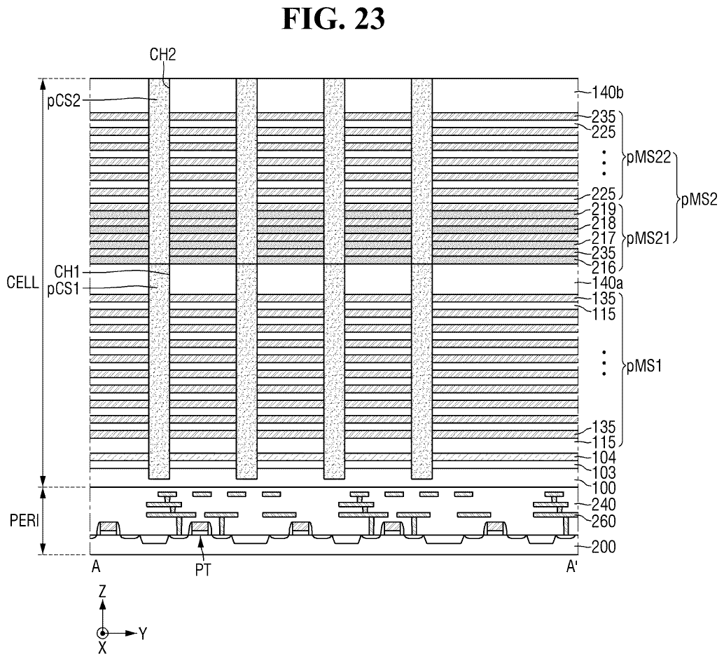

Referring to FIG. 23, a first channel hole CH1 which penetrates (i.e., extends into) the first preliminary mold pMS1 in the cell array region CA may be formed. A first preliminary channel pCS1 which fills the first channel hole CH1 may be formed. In some embodiments, the first preliminary channel pCS1 may penetrate (i.e., extend into) the source sacrificial film 103 and the source layer 102, and may be connected to the cell substrate 100.

The first preliminary channel pCS1 may include a material having an etching selectivity with respect to the first mold insulating film 115 and the first mold sacrificial film 135. As an example, the first preliminary channel pCS1 may include polysilicon.

Subsequently, a second preliminary mold pMS2 and a second interlayer insulating film 140b are formed. The second preliminary mold pMS2 may include a second-1 preliminary mold pMS21 and a second-2 preliminary mold pMS22 which are stacked in order. The second-1 preliminary mold pMS21 may include a plurality of second mold sacrificial films 235 and a plurality of first insulating films 216, 217, 218 and 219 that are alternately stacked. The second-2 preliminary mold pMS22 may include a plurality of second mold sacrificial films 235 and a plurality of second insulation layers 225 that are alternately stacked. Since formation of the second preliminary mold pMS2 and the second interlayer insulating film 140b is similar to formation of the first preliminary mold pMS1 and the first interlayer insulating film 140a, detailed descriptions thereof will be omitted. Accordingly, the second preliminary mold pMS2 may include a plurality of second mold sacrificial films 235 and a plurality of second mold insulating films 216, 217, 218, 219, and 225 that are alternately stacked on the cell substrate 100. Furthermore, cach second mold sacrificial film 235 of the second preliminary mold pMS2 may include a connection region CR exposed from other second mold sacrificial films 235 (e.g., see FIG. 16).

A second channel hole CH2 which penetrates (i.e., extends into) the second preliminary mold pMS2 may be formed on the first preliminary channel pCS1. Accordingly, the channel hole CH including the first channel hole CH1 and the second channel hole CH2 may be formed. A second preliminary channel pCS2 which fills the second channel hole CH2 may be formed. Since formation of the second preliminary channel pCS2 is similar to formation of the first preliminary channel pCS1, a detailed description thereof will be omitted.

Due to a difference in concentration of impurities in the first insulating films 216, 217, 218, and 219, the width of the second channel hole CH2 in the second-1 preliminary mold pMS21 may be constant. Also, the width of the lowermost part of the second channel hole CH2 may be the same as the width of the uppermost part of the first channel hole CH1. Therefore, the side wall of the channel hole CH may not include a step.

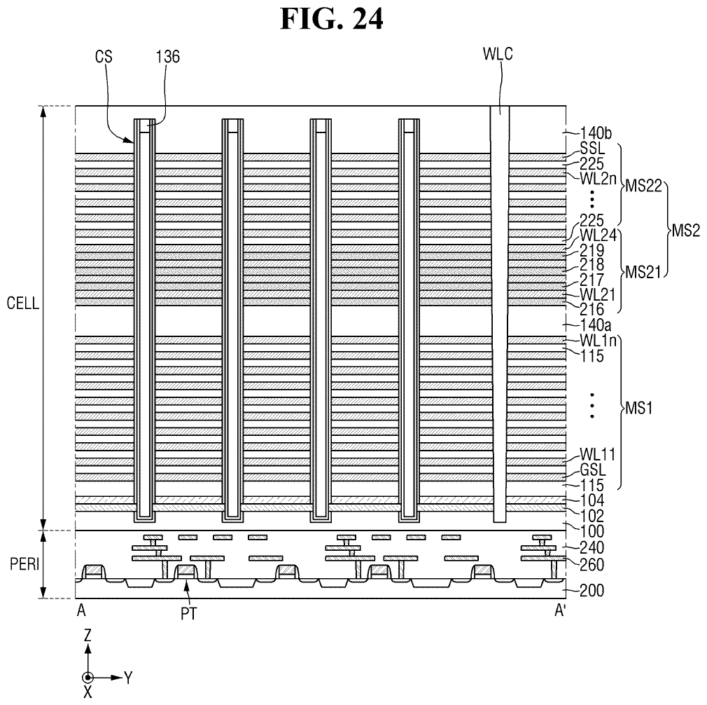

Referring to FIG. 24, the first preliminary channel pCS1 and the second preliminary channel pCS2 may be removed. The channel structure CS which replaces the region from which the first preliminary channel pCS1 and the second preliminary channel pCS2 are removed may then be formed. Therefore, the channel structure CS penetrating (i.e., extending) through the first preliminary mold pMS1 and the second preliminary mold pMS2 may be formed. The channel structure CS may include the first channel hole CH1 and the second channel hole CH2.

Subsequently, the word line cutting region WLC is formed. The word line cutting region WLC may cut the first preliminary mold pMS1 and the second preliminary mold pMS2. In some other embodiments, the word line cutting region WLC may be formed simultaneously with the first preliminary channel pCS1 and the second preliminary channel pCS2. Therefore, the word line cutting region WLC may have a shape similar to the first preliminary channel pCS1 and the second preliminary channel pCS2.

After that, the mold sacrificial films 135 and 235 may be removed, using the word line cutting region WLC. Since the mold sacrificial films 135 and 235 have etching selectivity with respect to the mold insulating films 115, 216, 217, 218, 219 and 225, they may be selectively removed. After that, the gate electrodes GSL, WL11 to WL1n, WL21 to WL2n, and SSL which replace the region from which the mold sacrificial films 135 and 235 are removed may be formed. Thus, the first mold stack MS1 including a plurality of first gate electrodes GSL and WL11 to WL1n and the second mold stack MS2 including a plurality of second gate electrodes WL21 to WL2n and SSL may be formed. After the first mold stack MS1 and the second mold stack MS2 are formed, the word line cutting regions WLC may be filled with an insulating material.

The memory device described above with reference to FIG. 14 may be manufactured, accordingly.

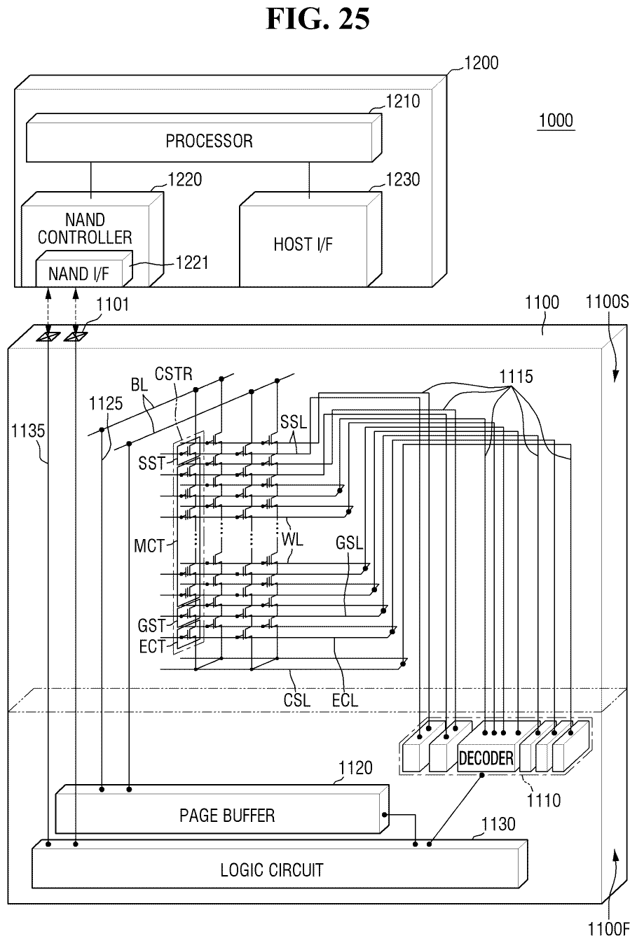

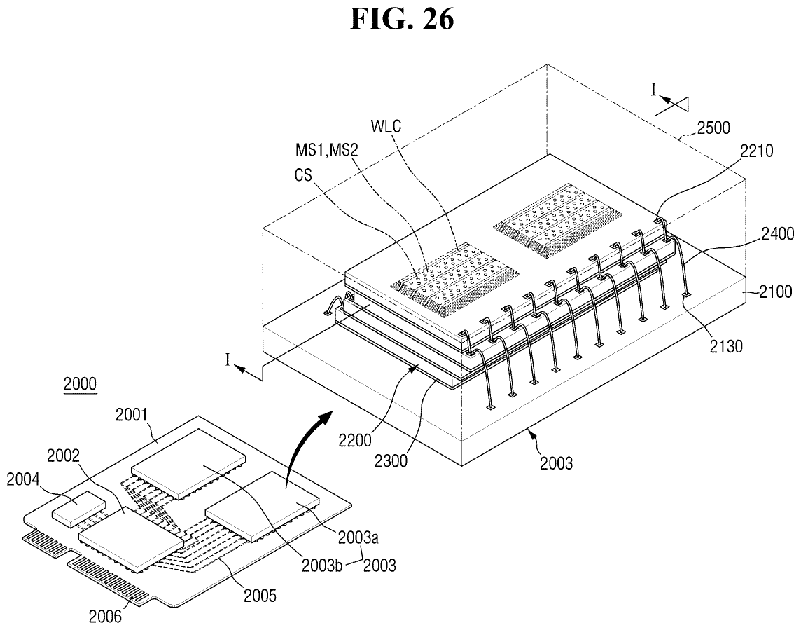

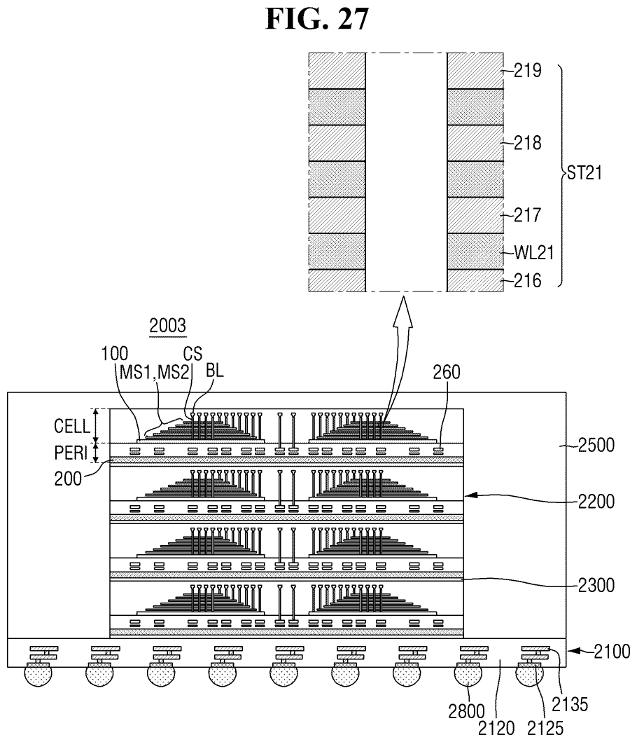

FIG. 25 is an example block diagram for describing an electronic system according to some embodiments. FIG. 26 is an example perspective view for describing an electronic system according to some embodiments. FIG. 27 is a schematic cross-sectional view taken along line I-I of FIG. 26.

Referring to FIG. 25, an electronic system 1000 according to some embodiments may include a semiconductor memory device 1100, and a controller 1200 that is electrically connected to the semiconductor memory device 1100. The electronic system 1000 may be a storage device that includes one or multiple semiconductor memory devices 1100, or an electronic device that includes the storage device. For example, the electronic system 1000 may be an SSD device (solid state drive device), a USB (Universal Serial Bus), a computing system, a medical device or a communication device that includes one or multiple semiconductor memory devices 1100.

The semiconductor memory device 1100 may be a non-volatile memory device (e.g., a NAND flash memory device), and may be, for example, the semiconductor memory device explained above with reference to FIGS. 11 to 21. The semiconductor memory device 1100 may include a first structure 1100F, and a second structure 1100S on the first structure 1100F.

The first structure 1100F may be a peripheral circuit structure that includes a decoder circuit 1110 (e.g., the row decoder 33 of FIG. 11), a page buffer 1120 (e.g., the page buffer 35 of FIG. 11), and a logic circuit 1130 (e.g., the control logic 37 of FIG. 11).

The second structure 1100S may include the common source line CSL, a plurality of bit lines BL, and a plurality of cell strings CSTR explained above with reference to FIG. 12. The cell strings CSTR may be connected to the decoder circuit 1110 through the word line WL, at least one string selection line SSL, and at least one ground selection line GSL. In addition, the cell strings CSTR may be connected to the page buffer 1120 through the bit lines BL. In some embodiments, an erase control transistor ECT may be placed between the common source line CSL and the ground selection transistor GST. The common source line CSL may be commonly connected to the sources of the erase control transistors ECT. Further, an erase control line ECL may be placed between the common source line CSL and the ground selection line GSL. The erase control line ECL may be used as the gate electrode of the erase control transistor ECT. The erase control transistors ECT may generate a gate induced drain leakage (GIDL) to perform the erase operation of the memory cell array.

In some embodiments, the common source line CSL and the cell strings CSTR may be electrically connected to the decoder circuit 1110 through first connection wirings 1115 extending from the first structure 1100F to the second structure 1100S.

In some embodiments, the bit lines BL may be electrically connected to the page buffer 1120 through the second connection wirings 1125 extending from the first structure 1100F to the second structure 1100S.

The semiconductor memory device 1100 may communicate with the controller 1200 through an I/O pad 1101 electrically connected to the logic circuit 1130 (e.g., the control logic 37 of FIG. 11). The I/O pad 1101 may be electrically connected to the logic circuit 1130 through the I/O connection wiring 1135 extending from the inside of the first structure 1100F to the second structure 1100S.

The controller 1200 may include a processor 1210, a NAND controller 1220, and a host interface 1230. In some embodiments, the electronic system 1000 may include a plurality of semiconductor memory devices 1100, and in this case, the controller 1200 may control the plurality of semiconductor memory devices 1100.

The processor 1210 may control the operation of the overall electronic system 1000 including the controller 1200. The processor 1210 may operate according to a predetermined firmware, and may control the NAND controller 1220 to access the semiconductor memory device 1100. The NAND controller 1220 may include a NAND interface 1221 that processes communication with the semiconductor memory device 1100. Control command for controlling the semiconductor memory device 1100, data to be recorded in the memory cell transistors MCT of the semiconductor memory device 1100, data to be read from the memory cell transistors MCT of the semiconductor memory device 1100, and the like may be transmitted through the NAND interface 1221. The host interface 1230 may provide a communication function between the electronic system 1000 and an external host. When the control command is received from the external host through the host interface 1230, the processor 1210 may control the semiconductor memory device 1100 in response to the control command.

Referring to FIG. 26, an electronic system 2000 according to some embodiments may include a main board 2001, a main controller 2002 mounted on the main board 2001, one or more semiconductor packages 2003, and a DRAM 2004. The semiconductor package 2003 and the DRAM 2004 may be connected to the main controller 2002 by wiring patterns 2005 formed on the main board 2001.

The main board 2001 may include a connector 2006 including a plurality of fins coupled to an external host. In the connector 2006, the number and placement of the plurality of fins may vary depending on the communication interface between the electronic system 2000 and the external host. In some embodiments, the electronic system 2000 may communicate with the external host according to any one of interfaces such as M-Phy for USB (Universal Serial Bus), PCI-Express (Peripheral Component Interconnect Express), SATA (Serial Advanced Technology Attachment), and UFS (Universal Flash Storage). In some embodiments, the electronic system 2000 may operate by power supplied from the external host through the connector 2006. The electronic system 2000 may further include a PMIC (Power Management Integrated Circuit) that distributes the power supplied from the external host to the main controller 2002 and the semiconductor package 2003.

The main controller 2002 may record data in the semiconductor package 2003 or read data from the semiconductor package 2003, and may improve the operating speed of the electronic system 2000.

The DRAM 2004 may be a buffer memory for relieving a speed difference between the semiconductor package 2003, which is a data storage space, and the external host. The DRAM 2004 included in the electronic system 2000 may also operate as a kind of cache memory, and may also provide a space for temporarily storing data in the control operation on the semiconductor package 2003. When the DRAM 2004 is included in the electronic system 2000, the main controller 2002 may further include a DRAM controller for controlling the DRAM 2004, in addition to a NAND controller for controlling the semiconductor package 2003.

The semiconductor package 2003 may include a first semiconductor package 2003a and a second semiconductor package 2003b that are spaced apart from each other. The first semiconductor package 2003a and the second semiconductor package 2003b may each be a semiconductor package that includes a plurality of semiconductor chips 2200. The first semiconductor package 2003a and the second semiconductor package 2003b may each include a package substrate 2100, semiconductor chips 2200 on the package substrate 2100, adhesive layers 2300 placed on the lower faces of each of the semiconductor chips 2200, a connecting structure 2400 for electrically connecting the semiconductor chips 2200 and the package substrate 2100, and a molding layer 2500 that covers the semiconductor chips 2200 and the connecting structure 2400 on the package substrate 2100.

The package substrate 2100 may be a printed circuit board (PCB) that includes package upper pads 2130. Each semiconductor chip 2200 may include an I/O pad 2210. The I/O pad 2210 may correspond to the I/O pad 1101 of FIG. 25.

In some embodiments, the connecting structure 2400 may be a bonding wire that electrically connects the I/O pad 2210 and the package upper pads 2130. Therefore, in each of the first semiconductor package 2003a and the second semiconductor package 2003b, the semiconductor chips 2200 may be electrically connected to each other by a bonding wire type, and may be electrically connected to the package upper pads 2130 of the package substrate 2100. In some embodiments, in each of the first semiconductor package 2003a and the second semiconductor package 2003b, the semiconductor chips 2200 may be electrically connected to each other by a connecting structure including a through electrode (e.g., Through Silicon Via, TSV) instead of the connecting structure 2400 of the bonding wire type.

In some embodiments, the main controller 2002 and the semiconductor chips 2200 may be included in a single package. In some embodiments, the main controller 2002 and the semiconductor chips 2200 are mounted on a separate interposer substrate different from the main board 2001, and the main controller 2002 and the semiconductor chips 2200 may be connected to each other by the wiring formed on the interposer substrate.

Referring to FIGS. 26 and 27, in some embodiments, the package substrate 2100 may be a printed circuit board (PCB). The package substrate 2100 may include a package substrate body portion 2120, package upper pads 2130 placed on an upper face of the package substrate body portion 2120, lower pads 2125 placed on a lower face of the package substrate body portion 2120 or exposed through the lower face, and inner wirings 2135 that electrically connect the upper pads 2130 and the lower pads 2125 inside the package substrate body portion 2120. The upper pads 2130 may be electrically connected to the connecting structures 2400. The lower pads 2125 may be connected to the wiring patterns 2005 of the main board 2001 of the electronic system 2000 through conductive connections 2800.

In the electronic system 2000 according to some embodiments, each of the semiconductor chips 2200 may include the semiconductor memory device described above with reference to FIGS. 11 to 21. For example, each of the semiconductor chips 2200 may include a peripheral circuit structure PERI, and a cell structure CELL stacked on the peripheral circuit structure PERI, as shown in FIG. 27. As an example, the peripheral circuit structure PERI may include the peripheral circuit board 200 and the peripheral circuit wiring structure 260 explained above with reference to FIGS. 11 to 21. Further, as an example, the cell structure CELL may include the cell substrate 100, the mold structures MS1 and MS2, the channel structure CS (e.g., including the channel hole CH), the word line cutting region WLC, the bit line BL, and the like explained above with reference to FIGS. 11 to 21.

As used herein, the terms “comprises”, “comprising”, “includes”, “including”, “has”, “having” and any other variations thereof specify the presence of the stated features, steps, operations, elements, components, and/or groups but do not preclude the presence or addition of one or more other features, steps, operations, elements, components, and/or groups thereof.

Although example embodiments of the present disclosure have been described above with reference to the accompanying drawings, the present disclosure is not limited to the above example embodiments, and may be fabricated in various forms. Those skilled in the art will appreciate that the present disclosure may be embodied in other specific forms without changing the essential features of the present disclosure. Accordingly, the above-described example embodiments should be understood in all respects as illustrative and not restrictive.

What is claimed is:

1. A semiconductor memory device comprising:
a first stacked structure comprising a plurality of first interlayer insulating films;
a second stacked structure comprising a plurality of second interlayer insulating films on the first stacked structure; and
a hole that extends into the first stacked structure and the second stacked structure,
wherein the plurality of second interlayer insulating films comprise a plurality of first films that include first impurities, and a plurality of second films that are free of the first impurities.

2. The semiconductor memory device of claim 1, wherein the plurality of first films are between the first stacked structure and the plurality of second films.

3. The semiconductor memory device of claim 1, wherein a concentration of the first impurities included in the plurality of first films increases toward the first stacked structure.

4. The semiconductor memory device of claim 1, wherein the first impurities comprise at least one of fluorine (F) or phosphorus (P).

5. The semiconductor memory device of claim 1, wherein the plurality of first interlayer insulating films are free of the first impurities.

6. The semiconductor memory device of claim 1, wherein the plurality of first interlayer insulating films comprise a plurality of third films that include second impurities, and a plurality of fourth films that are free of the second impurities.

7. The semiconductor memory device of claim 6, wherein the plurality of fourth films are between the plurality of third films and the second stacked structure.

8. The semiconductor memory device of claim 6, wherein a concentration of the second impurities included in the plurality of third films decreases toward the second stacked structure.

9. The semiconductor memory device of claim 1, wherein side walls of the hole are free of a stepped portion.

10. A semiconductor memory device comprising:
a first stacked structure comprising a plurality of first interlayer insulating films;
a second stacked structure comprising a plurality of second interlayer insulating films on the first stacked structure; and
a hole that extends into the first stacked structure and the second stacked structure,
wherein the plurality of second interlayer insulating films comprise a plurality of first films on the first stacked structure, and a plurality of second films on the plurality of first films,
wherein one of the plurality of first interlayer insulating films that is closest to the second stacked structure is free of impurities, and
wherein one of the plurality of first films that is closest to the first stacked structure includes the impurities.

11. The semiconductor memory device of claim 10, wherein a slope of side walls of a first portion of the hole in the plurality of first films is greater than a slope of side walls of a second portion of the hole in the first stacked structure.

12. The semiconductor memory device of claim 10, wherein a slope of side walls of a first portion of the hole in the plurality of first films is greater than a slope of side walls of a second portion of the hole in the plurality of second films.

13. The semiconductor memory device of claim 10, wherein a slope of side walls of a first portion of the hole in the plurality of first films is the same as a slope of side walls of a second portion of the hole in the plurality of second films.

14. The semiconductor memory device of claim 10, wherein a width of the hole at a lowermost portion of the second stacked structure is the same as a width of the hole at an uppermost portion of the first stacked structure.

15. The semiconductor memory device of claim 10, wherein each of the plurality of first films includes the impurities.

16. The semiconductor memory device of claim 15, wherein a concentration of the impurities included in the plurality of first films increases toward the first stacked structure.

17. The semiconductor memory device of claim 10, wherein the impurities comprise at least one of fluorine (F) or phosphorus (P).

18. An electronic system comprising:
a main board;
a semiconductor memory device on the main board; and
a controller electrically connected to the semiconductor memory device on the main board, the semiconductor memory device comprising:
a cell substrate;
a first mold stack comprising a plurality of first gate electrodes and a plurality of first mold insulating films alternately stacked on the cell substrate;
a second mold stack comprising a plurality of second gate electrodes and a plurality of second mold insulating films alternately stacked on the first mold stack; and
a channel structure that extends into the first mold stack and the second mold stack,
wherein the plurality of second mold insulating films comprise a plurality of first insulating films that include impurities, and a plurality of second insulating films that are free of the impurities, and
wherein the channel structure is free of a stepped portion.

19. The electronic system of claim 18, wherein the plurality of first insulating films are between the first mold stack and the plurality of second insulating films.

20. The electronic system of claim 18, wherein a concentration of the impurities included in the plurality of first insulating films increases toward the first mold stack.
